(19) United States
(12) Patent Application Publication
(10) Pub. No.: US 2025/0364506 A1
(43) Pub. Date: Nov. 27, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yasutomo Sakurai, Kawasaki Kanagawa (JP); Yutaka Horie, Mitaka Tokyo (JP); Shugo Suzuki, Hanno Saitama (JP); Hitoshi Imi, Yokohama Kanagawa (JP); Masahiro Koyama, Machida Tokyo (JP)

(21) Appl. No.: 18/828,963

(22) Filed: Sep. 9, 2024

(30) Foreign Application Priority Data
May 21, 2024 (JP) 2024-082673

(51) Int. Cl. H01L 25/11; H01L 23/00; H01L 23/48; H01L 23/66

(52) U.S. Cl. CPC H01L 25/112; H01L 23/481; H01L 23/66; H01L 24/16; H01L 24/17; H01L 2224/1613; H01L 2224/17181; H01L 2924/1205; H01L 2924/13055; H01L 2924/13062; H01L 2924/13091

(57) ABSTRACT

According to one embodiment, a semiconductor device includes a first switch provided with a first electrode and a second electrode, a second switch provided with a third electrode and a fourth electrode, a first capacitor including a first wiring layer connected to the third electrode, a second wiring layer connected to the first electrode, and a first dielectric layer, a substrate, a third wiring layer connected to the first wiring layer and applied with a first voltage, a fourth wiring layer connected to the second wiring layer and applied with a second voltage, and a fifth wiring layer connected to the second and fourth electrodes, and applied with a third voltage. The first capacitor is arranged between the first and second switches. The third electrode faces the first electrode. The fourth electrode faces the second electrode and is connected to the second electrode in series.

### CROSS-REFERENCE TO RELATED APPLICATIONS

This application is based upon and claims the benefit of priority from Japanese Patent Application No. 2024-082673, filed May 21, 2024, the entire contents of which are incorporated herein by reference.

### FIELD

Embodiments described herein relate generally to a semiconductor device.

### BACKGROUND

A semiconductor device that performs power conversion and control is known.

### BRIEF DESCRIPTION OF THE DRAWINGS

FIG. 1 is a circuit diagram showing an example of a circuit configuration of a semiconductor device according to a first embodiment.

FIG. 2 is a circuit diagram showing an application example of the semiconductor device according to the first embodiment.

FIG. 3 is a circuit diagram showing an example of a configuration of each switching element in the semiconductor device according to the first embodiment.

FIG. 4 is a perspective view showing an example of a structure of the semiconductor device according to the first embodiment.

FIG. 5 is a sectional view showing an example of a sectional structure of the semiconductor device according to the first embodiment.

FIG. 6 is a sectional view showing another example of a sectional structure of the semiconductor device according to the first embodiment.

FIG. 7 is a plan view showing an example of a planar structure of the semiconductor device according to the first embodiment when viewed from the position of a line a-a in FIGS. 5 and 6.

FIG. 8 is a plan view showing an example of a planar structure of the semiconductor device according to the first embodiment when viewed from the position of a line b-b in FIGS. 5 and 6.

FIG. 9 is a plan view showing an example of a planar structure of the semiconductor device according to the first embodiment when viewed from the position of a line c-c in FIGS. 5 and 6.

FIG. 10 is a plan view showing an example of a planar structure of the semiconductor device according to the first embodiment when viewed from the position of a line d-d in FIGS. 5 and 6.

FIG. 11 is a view showing a high frequency current path of the semiconductor device according to the first embodiment.

FIG. 12 is a circuit diagram showing an example of a circuit configuration of a semiconductor device according to a second embodiment.

FIG. 13 is a circuit diagram showing an example of a configuration of each switching element in the semiconductor device according to the second embodiment.

FIG. 14 is a sectional view showing an example of a sectional structure of the semiconductor device according to the second embodiment.

FIG. 15 is a sectional view showing another example of a sectional structure of the semiconductor device according to the second embodiment.

FIG. 16 is a plan view showing an example of a planar structure of the semiconductor device according to the second embodiment when viewed from the position of a line a-a in FIGS. 14 and 15.

FIG. 17 is a plan view showing an example of a planar structure of the semiconductor device according to the second embodiment when viewed from the position of a line b-b in FIGS. 14 and 15.

FIG. 18 is a plan view showing an example of a planar structure of the semiconductor device according to the second embodiment when viewed from the position of a line c-c in FIGS. 14 and 15.

FIG. 19 is a plan view showing an example of a planar structure of the semiconductor device according to the second embodiment when viewed from the position of a line d-d in FIGS. 14 and 15.

FIG. 20 is a view showing high frequency current paths of the semiconductor device according to the second embodiment, and a magnetic flux generated by a high frequency current.

FIG. 21 is a circuit diagram showing an example of a circuit configuration of a semiconductor device according to a third embodiment.

FIG. 22 is a circuit diagram showing an example of a configuration of each switching element in the semiconductor device according to the third embodiment.

FIG. 23 is a sectional view showing an example of a sectional structure of the semiconductor device according to the third embodiment.

FIG. 24 is a sectional view showing another example of a sectional structure of the semiconductor device according to the third embodiment.

FIG. 25 is a view showing a high frequency current path of the semiconductor device according to the third embodiment.

FIG. 26 is a circuit diagram showing an example of a circuit configuration of a semiconductor device according to a fourth embodiment.

FIG. 27 is a circuit diagram showing an example of a configuration of each switching element in the semiconductor device according to the fourth embodiment.

FIG. 28 is a sectional view showing an example of a sectional structure of the semiconductor device according to the fourth embodiment.

FIG. 29 is a sectional view showing another example of a sectional structure of the semiconductor device according to the fourth embodiment.

FIG. 30 is a view showing high frequency current paths of the semiconductor device according to the fourth embodiment, and a magnetic flux generated by a high frequency current.

### DETAILED DESCRIPTION

In general, according to one embodiment, a semiconductor device includes a first switch provided with a first electrode and a second electrode in a vicinity of a front surface, a second switch provided with a third electrode and a fourth electrode in a vicinity of a front surface, a first capacitor including a first wiring layer connected to the third electrode, a second wiring layer connected to the first electrode, and a first dielectric layer arranged between the first wiring layer and the second wiring layer, a substrate incorporating the first switch, the second switch, and the first capacitor, a third wiring layer connected to the first wiring layer and applied with a first voltage, a fourth wiring layer connected to the second wiring layer and applied with a second voltage higher than the first voltage, and a fifth wiring layer connected to the second electrode and the fourth electrode, and applied with a third voltage in a range of not less than the first voltage and not more than the second voltage. The first capacitor is arranged between the first switch and the second switch. The third electrode is arranged to face the first electrode in a first direction. The fourth electrode is arranged to face the second electrode in the first direction and connected to the second electrode in series.

Hereinafter, embodiments will be described with reference to the accompanying drawings. The dimensions and ratios in the drawings do not necessarily match the actuality. Note that in the following description, the same reference numerals denote constituent elements having substantially the same functions and configurations, and a repetitive description may be omitted. To particularly discriminate elements having the same configuration, characters or numbers different from each other may be added to the end of the same reference numeral. All statements made about one embodiment also apply as statements made to another embodiment, unless expressly or explicitly excluded.

### 1. First Embodiment

A semiconductor device according to the first embodiment will be described. A semiconductor device that performs power conversion and control by alternatively driving two switching elements will be taken as an example and described below. The semiconductor device according to this embodiment is applied to, for example, an AC-DC converter, a DC-AC inverter, a DC-DC converter, and the like.

### 1.1 Circuit Configuration of Semiconductor Device

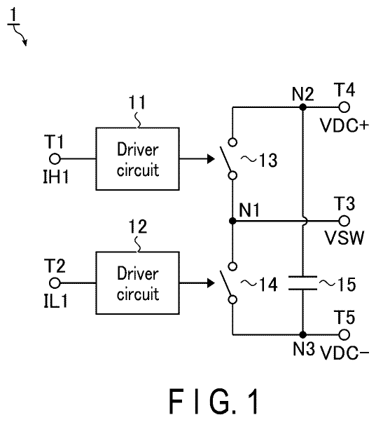

A circuit configuration of a semiconductor device will be described with reference to FIG. 1. FIG. 1 is a circuit diagram showing an example of the circuit configuration of the semiconductor device.

A semiconductor device 1 is, for example, a power supply module. The semiconductor device 1 includes control terminals T1 and T2, driver circuits 11 and 12, input/output terminals T3, T4, and T5, switching elements (switches) 13 and 14, and a capacitor 15.

The control terminal T1 is a terminal to which a control signal IH1 is externally input. The control signal IH1 is a signal for controlling the operation of the driver circuit 11. The control signal IH1 is, for example, a signal at High (“H”) level or a signal at Low (“L”) level.

The control terminal T2 is a terminal to which a control signal IL1 is externally input. The control signal IL1 is a signal for controlling the operation of the driver circuit 12. The control signal IL1 is, for example, a signal at “H” level or a signal at “L” level.

The driver circuit 11 is a circuit that drives the switching element 13. The driver circuit 11 is connected to the control terminal T1 and the switching element 13. The driver circuit 11 turns on or off the switching element 13 based on the control signal IH1.

The driver circuit 11 turns on the switching element 13 in accordance with an ON request signal for the switching element 13 by the control signal IH1. The driver circuit 11 turns off the switching element 13 in accordance with an OFF request signal for the switching element 13 by the control signal IH1.

The driver circuit 12 is a circuit that drives the switching element 14. The driver circuit 12 is connected to the control terminal T2 and the switching element 14. The driver circuit 12 turns on or off the switching element 14 based on the control signal IL1.

The driver circuit 12 turns on the switching element 14 in accordance with an ON request signal for the switching element 14 by the control signal IL1. The driver circuit 12 turns off the switching element 14 in accordance with an OFF request signal for the switching element 14 by the control signal IL1.

The control signals IH1 and IL1 are controlled to alternately turn on or off the switching elements 13 and 14. Accordingly, the driver circuits 11 and 12 alternately turn on or off the switching elements 13 and 14. In other words, when one of the switching elements 13 and 14 is in the ON state, the other is in the OFF state.

Each of the input/output terminals T3 to T5 is an input terminal or an output terminal. The input/output terminal T3 is connected to a node N1. The input/output terminal T4 is connected to a node N2. The input/output terminal T5 is connected to a node N3. A voltage VDC− is a DC voltage applied to the node N3, that is, the input/output terminal T5. The voltage VDC− is, for example, a ground voltage GND. A voltage VDC+ is a DC voltage applied to the node N2, that is, the input/output terminal T4. The voltage VDC+ is a voltage higher than the voltage VDC−. A voltage VSW is a voltage applied to the node N1, that is, the input/output terminal T3. The voltage VSW is switched between the voltage VDC− and the voltage VDC+. The voltage VSW may exceed the voltage VDC+ due to a surge that occurs caused by the parasitic inductance of the wiring when switching the switching elements 13 and 14. In the steady state, the voltage VSW is in a range of the voltage VDC− or more to the voltage VDC+ or less.

The switching element 13 includes a first end, a second end, and a third end. The first end of the switching element 13 is connected to the driver circuit 11. The second end of the switching element 13 is connected to the node N2. The third end of the switching element 13 is connected to the node N1. The switching element 14 includes a first end, a second end, and a third end. The first end of the switching element 14 is connected to the driver circuit 12. The second end of the switching element 14 is connected to the node N1. The third end of the switching element 14 is connected to the node N3. The switching elements 13 and 14 include, for example, at least one of an n-channel MOSFET (Metal Oxide Semiconductor Field Effect Transistor), a p-channel MOSFET, a GaN (Gallium Nitride) transistor, an SiC (Silicon Carbide) transistor, an IGBT (Insulated Gate Bipolar Transistor), and a JFET (Junction Field Effect Transistor). The switching elements 13 and 14 are normally-off switching elements.

One electrode of the capacitor 15 is connected to the node N2. The other electrode of the capacitor 15 is connected to the node N3. In other words, the capacitor 15 is connected to both ends of the switching elements 13 and 14 connected in series. With this, the capacitor 15 functions as a snubber capacitor configured to reduce the surge that may occur caused by the parasitic inductance of the wiring when switching ON or OFF of the switching elements 13 and 14.

Depending on a configuration of a circuit (not shown) connected to the input/output terminals T3 to T5, each of the input/output terminals T3 to T5 serves as an input terminal or an output terminal.

For example, in a case where the semiconductor device 1 and a circuit connected to the input/output terminals T3 to T5 form a synchronous rectification boost converter, the input/output terminal T3 serves as an input terminal, and the input/output terminals T4 and T5 serve as output terminals.

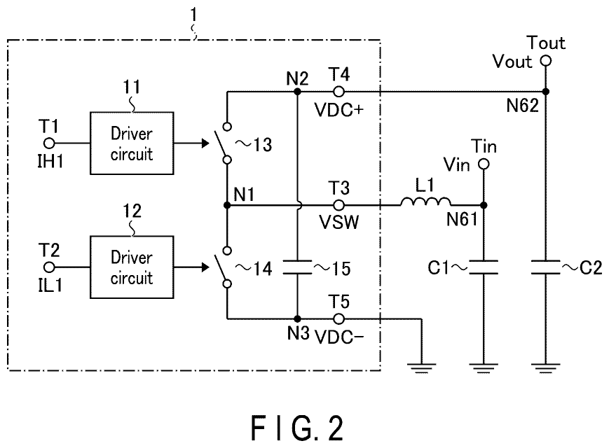

FIG. 2 is a circuit diagram showing an application example (synchronous rectification boost converter) of the semiconductor device 1. As shown in FIG. 2, the synchronous rectification boost converter includes the semiconductor device 1, terminals Tin and Tout, a coil L1, and capacitors C1 and C2.

The terminal Tin is connected to a node N61. An input voltage Vin is applied to the terminal Tin.

The terminal Tout is connected to a node N62. An output voltage Vout is output from the terminal Tout.

One end of the coil L1 is connected to the node N61. The other end of the coil L1 is connected to the input/output terminal T3.

One electrode of the capacitor C1 is connected to the node N61. The other electrode of the capacitor C1 is grounded.

The input/output terminal T4 is connected to the node N62.

One electrode of the capacitor C2 is connected to the node N62. The other electrode of the capacitor C2 is grounded.

The input/output terminal T5 is grounded.

When the switching element 13 is turned off and the switching element 14 is turned on, the input/output terminal T3 is grounded via the switching element 14, and a current flows from the terminal Tin to the coil L1, the input/output terminal T3, the switching element 14, and the input/output terminal T5. At this time, magnetic energy is stored in the coil L1.

Thereafter, when the switching element 13 is turned on and the switching element 14 is turned off, the coil L1 emits the magnetic energy, and a current flows from the input/output terminal T3 to the input/output terminal T4 through the switching element 13. With this, charges are stored in the capacitor C2, and the voltage of the node N62 increased. The increased voltage is output from the terminal Tout as the voltage Vout.

Alternatively, for example, in a case where the semiconductor device 1 and a circuit connected to the input/output terminals T3 to T5 form one of a half-bridge converter, a full-bridge converter, a half-bridge LLC converter, a phase-shifted full-bridge converter, and the like, the input/output terminal T3 serves as an output terminal, and the input/output terminals T4 and T5 serve as input terminals. Also in a case where the semiconductor device 1 and a circuit connected to the input/output terminals T3 to T5 form a DC-AC inverter, the input/output terminal T3 serves as an output terminal, and the input/output terminals T4 and T5 serve as input terminals.

A case where the switching elements 13 and 14 are n-channel MOSFETs will be described below as an example.

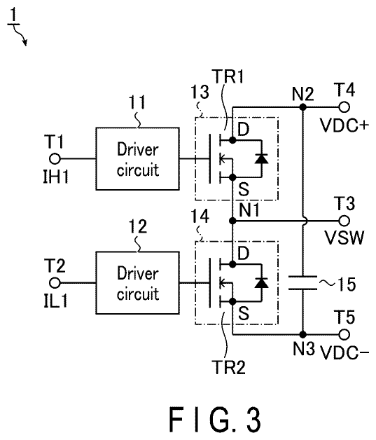

FIG. 3 is a circuit diagram showing an example of a configuration of each switching element in the semiconductor device 1.

As shown in FIG. 3, the switching element 13 is a transistor TR1. The switching element 14 is a transistor TR2. The transistors TR1 and TR2 are n-channel MOSFETs. The transistors TR1 and TR2 are normally-off transistors.

The gate electrode (control electrode) of the switching element 13 is connected to the driver circuit 11. The drain electrode of the switching element 13 is connected to the node N2. The source electrode of the switching element 13 is connected to the node N1. The gate electrode (control electrode) of the switching element 14 is connected to the driver circuit 12. The drain electrode of the switching element 14 is connected to the node N1. The source electrode of the switching element 14 is connected to the node N3. The source electrode of the switching element 13 and the drain electrode of the switching element 14 are connected in series.

### 1.2 Structure of Semiconductor Device

The structure of the semiconductor device 1 will be described.

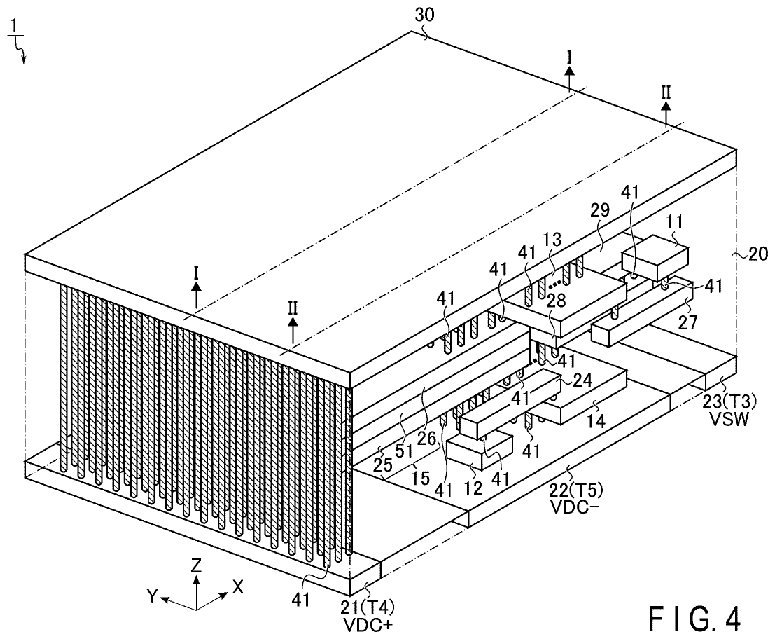

FIG. 4 is a perspective view showing an example of a structure of the semiconductor device 1. As shown in FIG. 4, the semiconductor device 1 includes a substrate 20 incorporating the driver circuits 11 and 12, the switching elements 13 and 14, and the capacitor 15. That is, the substrate 20 is a component incorporating substrate. The substrate 20 is, for example, a glass epoxy substrate. Note that in FIG. 4, the control terminals T1 and T2 are not shown.

Hereinafter, a plane parallel to the surface of the substrate 20 is defined as the X-Y plane. Directions perpendicularly intersecting each other in the X-Y plane are defined as the X direction and the Y direction. A direction intersecting the X-Y plane is defined as the Z direction. In the Z direction, a direction from the substrate 20 to a wiring layer 30 (to be described later) will also be referred to as the upward direction, and a direction from the substrate 20 to wiring layers 21, 22, and 23 (to be described later) will also be referred to as the downward direction. The upper surface of the substrate 20 will also be referred to as “the front surface of the substrate 20”, and the lower surface of the substrate 20 will also be referred to as “the back surface of the substrate 20”.

The wiring layers 21 to 23 are provided on the back surface of the substrate 20. The wiring layers 21 to 23 are arranged apart from each other in the X direction. The wiring layer 21 corresponds to the input/output terminal T4. The voltage VDC+ is applied to the wiring layer 21. The wiring layer 22 corresponds to the input/output terminal T5. The voltage VDC− is applied to the wiring layer 22. The wiring layer 23 corresponds to the input/output terminal T3. The voltage VSW is applied to the wiring layer 23. Hereinafter, the surface of the wiring layer 22 in contact with the substrate 20 will also be referred to as “the front surface of the wiring layer 22”, and the surface of the wiring layer 23 in contact with the substrate 20 will also be referred to as “the front surface of the wiring layer 23”.

The switching element 14 is provided above the wiring layer 22. The switching element 14 and the wiring layer 22 are connected via multiple vias 41.

Wiring layers 24, 25, and 28 are provided above the switching element 14. The wiring layers 24 and 25 are arranged apart from each other in the Y direction. The wiring layers 25 and 28 are arranged apart from each other in the X direction. The wiring layer 24 and the switching element 14 are connected via a via 41. The wiring layer 25 and the switching element 14 are connected via multiple vias 41. The wiring layer 28 and the switching element 14 are connected via multiple vias 41.

The driver circuit 12 is provided below the wiring layer 24. The driver circuit 12 and the switching element 14 are arranged apart from each other in the X direction. The driver circuit 12 and the wiring layer 24 are connected via a via 41. Note that the driver circuit 12 may not be incorporated in the substrate 20.

A dielectric layer 51 is provided on the wiring layer 25. A wiring layer 26 is provided on the dielectric layer 51. The wiring layer 25, the dielectric layer 51, and the wiring layer 26 form the capacitor 15. The capacitor 15 is arranged between the switching element 13 and the switching element 14.

A wiring layer 29 is provided above the wiring layer 28. The wiring layers 29 and 26 are arranged apart from each other in the X direction. The wiring layer 29 and the wiring layer 28 are connected via multiple vias 41.

The switching element 13 is provided above the wiring layers 26 and 29. The switching element 13 and the wiring layer 26 are connected via multiple vias 41. The switching element 13 and the wiring layer 29 are connected via multiple vias 41.

A wiring layer 27 is provided below the switching element 13. The wiring layer 27 and the switching element 13 are connected via a via 41.

The driver circuit 11 is provided above the wiring layer 27. The driver circuit 11 and the switching element 13 are arranged apart from each other in the X direction. The driver circuit 11 and the wiring layer 27 are connected via a via 41. Note that the driver circuit 11 may not be incorporated in the substrate 20.

The wiring layer 30 is provided on the front surface of the substrate 20. The wiring layer 30 and the wiring layer 21 are connected via multiple vias 41. The wiring layer 30 and the wiring layer 26 are connected via multiple vias 41. The wiring layer 30 and the switching element 13 are connected via multiple vias 41.

The wiring layers 21 to 30 are formed of a conductive material. The wiring layers 21 to 30 includes, for example, copper (copper foil). The via 41 is formed of a conductive material. The via 41 includes, for example, copper (copper plating). The dielectric layer 51 includes, for example, silicon or barium titanate. The dielectric layer 51 may include, for example, a nitride.

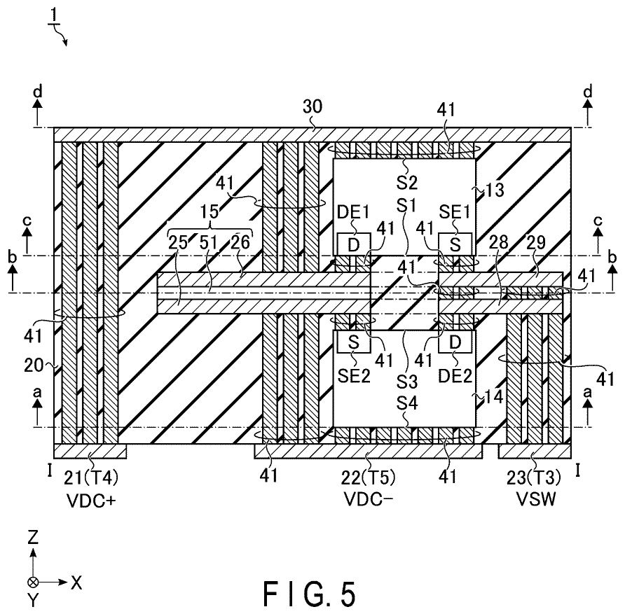

FIG. 5 is a sectional view showing an example of a sectional structure of the semiconductor device 1 taken along a line I-I in FIG. 4.

As shown in FIG. 5, the switching element 13 includes a surface S1 and a surface S2 facing the surface S1. Hereinafter, the surface S1 will also be referred to as “the front surface of the switching element 13”, and the surface S2 will also be referred to as “the back surface of the switching element 13”. A drain electrode DE1 and a source electrode SE1 are provided in the vicinity of the front surface of the switching element 13. The multiple vias 41 are provided between the switching element 13 and the wiring layer 30.

The switching element 14 includes a surface S3 and a surface S4 facing the surface S3. Hereinafter, the surface S3 will also be referred to as “the front surface of the switching element 14”, and the surface S4 will also be referred to as “the back surface of the switching element 14”. A source electrode SE2 and a drain electrode DE2 are provided in the vicinity of the front surface of the switching element 14. The multiple vias 41 are provided between the switching element 14 and the wiring layer 22.

The wiring layer 25 is provided above the switching element 14. The multiple vias 41 are provided between the end portion of the lower surface of the wiring layer 25 on the switching element 14 side and the source electrode SE2 of the switching element 14. In other words, the end portion of the lower surface of the wiring layer 25 on the switching element 14 side is in contact with the multiple vias 41. The source electrode SE2 of the switching element 14 is in contact with the multiple vias 41. That is, the wiring layer 25 is connected to the source electrode SE2 of the switching element 14 via the multiple vias 41. The multiple vias 41 are provided between the wiring layer 25 and the wiring layer 22. The wiring layer 25 functions as a wiring that supplies the voltage VDC−. The wiring layer 25 also functions as the other electrode of the capacitor 15. Hereinafter, the lower surface of the wiring layer 25 will also be referred to as “the front surface of the wiring layer 25”.

The dielectric layer 51 is provided on the wiring layer 25.

The wiring layer 26 is provided on the dielectric layer 51 and below the switching element 13. The multiple vias 41 are provided between the end portion of the upper surface of the wiring layer 26 on the switching element 13 side and the drain electrode DE1 of the switching element 13. In other words, the end portion of the upper surface of the wiring layer 26 on the switching element 13 side is in contact with the multiple vias 41. The drain electrode DE1 of the switching element 13 is in contact with the multiple vias 41. That is, the wiring layer 26 is connected to the drain electrode DE1 of the switching element 13 via the multiple vias 41. The multiple vias 41 are provided between the wiring layer 26 and the wiring layer 30. The wiring layer 26 functions as a wiring that supplies the voltage VDC+. The wiring layer 26 also functions as one electrode of the capacitor 15. Hereinafter, the upper surface of the wiring layer 26 will also be referred to as “the front surface of the wiring layer 26”.

The wiring layer 28 is provided above the switching element 14. The wiring layer 28 is provided in the same layer as the wiring layer 25. The multiple vias 41 are provided between the end portion of the lower surface of the wiring layer 28 on the switching element 14 side and the drain electrode DE2 of the switching element 14. In other words, the end portion of the lower surface of the wiring layer 28 on the switching element 14 side is in contact with the multiple vias 41. The drain electrode DE2 of the switching element 14 is in contact with the multiple vias 41. The multiple vias 41 are provided between the wiring layer 28 and the wiring layer 23. The wiring layer 28 functions as a wiring that supplies the voltage VSW.

The wiring layer 29 is provided above the wiring layer 28 and below the switching element 13. The wiring layer 29 is provided in the same layer as the wiring layer 26. The multiple vias 41 are provided between the wiring layer 29 and the wiring layer 28. The multiple vias 41 are provided between the end portion of the upper surface of the wiring layer 29 on the switching element 13 side and the source electrode SE1 of the switching element 13. In other words, the end portion of the upper surface of the wiring layer 29 on the switching element 13 side is in contact with the multiple vias 41. The source electrode SE1 of the switching element 13 is in contact with the multiple vias 41. The wiring layer 29 functions as a wiring that supplies the voltage VSW.

The multiple vias 41 are provided between the wiring layer 21 and the wiring layer 30. The wiring layer 30 functions as a wiring that supplies the voltage VDC+.

The wiring layer 21 is connected to the wiring layer 26 via the multiple vias 41, the wiring layer 30, and the multiple vias 41. The wiring layer 22 is connected to the wiring layer 25 via the multiple vias 41. The wiring layer 23 is connected to the source electrode SE1 of the switching element 13 via the multiple vias 41, the wiring layer 28, the multiple vias 41, the wiring layer 29, and the multiple vias 41. The wiring layer 23 is also connected to the drain electrode DE2 of the switching element 14 via the multiple vias 41, the wiring layer 28, and the multiple vias 41.

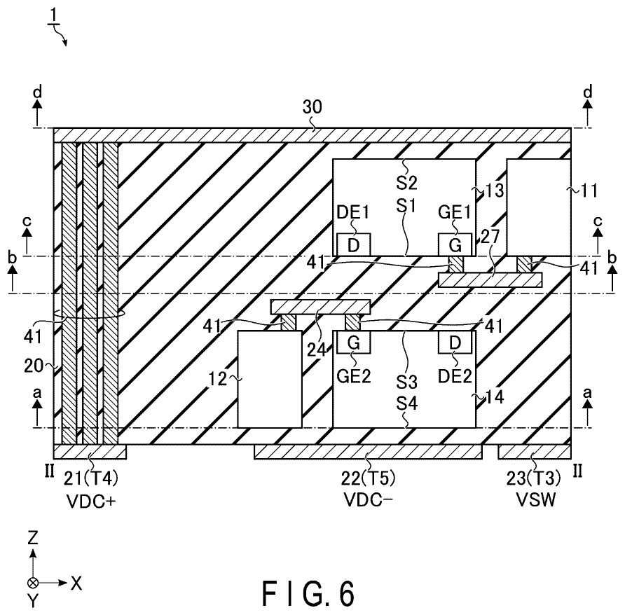

FIG. 6 is a sectional view showing an example of a sectional structure of the semiconductor device 1 taken along a line II-II in FIG. 4.

As shown in FIG. 6, a gate electrode GE1 is provided in the vicinity of the front surface of the switching element 13. A gate electrode GE2 is provided in the vicinity of the front surface of the switching element 14.

The wiring layer 24 is provided above the switching element 14. The via 41 is provided between the end portion of the lower surface of the wiring layer 24 on the switching element 14 side and the gate electrode GE2 of the switching element 14. The via 41 is provided between the end portion of the lower surface of the wiring layer 24 on the opposite side of the switching element 14 and the driver circuit 12.

The wiring layer 27 is provided below the switching element 13. The via 41 is provided between the end portion of the upper surface of the wiring layer 27 on the switching element 13 side and the gate electrode GE1 of the switching element 13. The via 41 is provided between the end portion of the upper surface of the wiring layer 27 on the opposite side of the switching element 13 and the driver circuit 11.

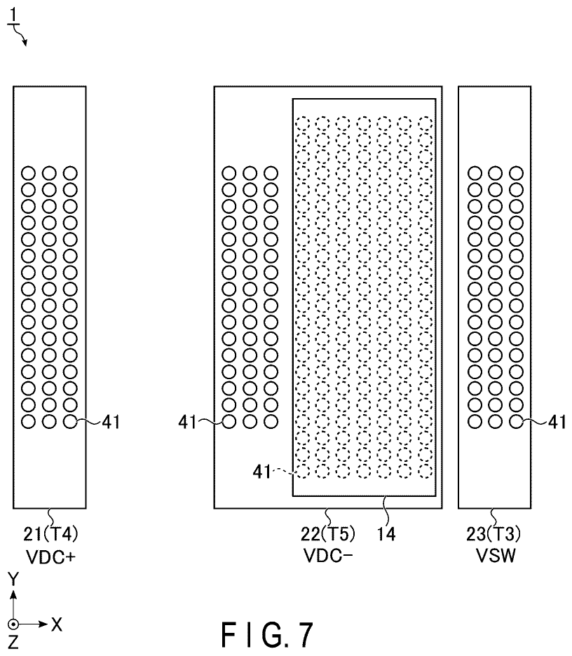

FIG. 7 is a plan view showing an example of a planar structure of the semiconductor device 1 when viewed in the downward direction from the position of a line a-a in FIGS. 5 and 6.

As shown in FIG. 7, the multiple vias 41 are provided on the wiring layer 21. The wiring layer 21 functions as an external connection terminal for the voltage VDC+.

The multiple vias 41 are provided on the wiring layer 22. The wiring layer 22 functions as an external connection terminal for the voltage VDC−. The switching element 14 is provided above the wiring layer 22. Note that FIG. 7 shows the back surface of the switching element 14. The multiple vias 41 provided between the wiring layer 22 and the switching element 14 are provided to dissipate the heat of the switching element 14. In other words, the wiring layer 22 also functions as the heat dissipation surface for the switching element 14.

The multiple vias 41 are provided on the wiring layer 23. The wiring layer 23 functions as an external connection terminal for the voltage VSW.

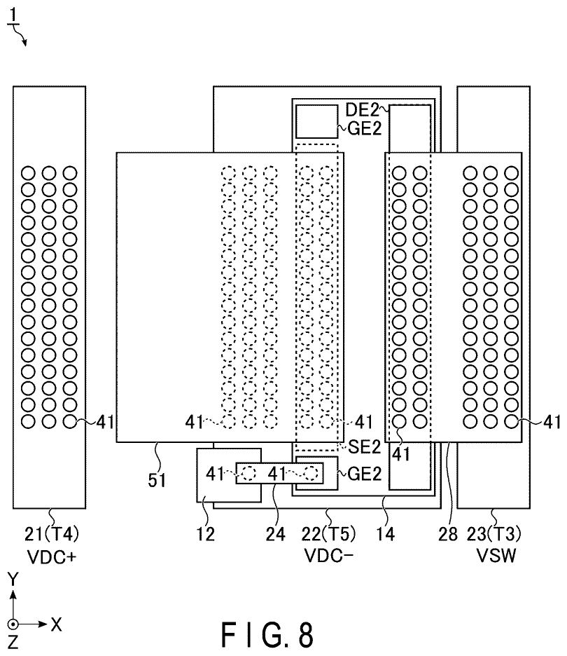

FIG. 8 is a plan view showing an example of a planar structure of the semiconductor device 1 when viewed in the downward direction from the position of a line b-b in FIGS. 5 and 6.

As shown in FIG. 8, the switching element 14 is provided above the wiring layer 22. Note that FIG. 8 shows the front surface of the switching element 14. The drain electrode DE2, the source electrode SE2, and two gate electrodes GE2 are provided in the vicinity of the front surface of the switching element 14.

The drain electrode DE2 is provided in the vicinity of the end portion of front surface of the switching element 14 on the wiring layer 23 side. The source electrode SE2 and the two gate electrodes GE2 are provided in the vicinity of the end portion of the front surface of the switching element 14 on the wiring layer 21 side. In other words, the drain electrode DE2 is arranged apart from the source electrode SE2 and the two gate electrodes GE2 in the X direction.

The two gate electrodes GE2 are provided in the vicinity of both ends of the front surface of the switching element 14 in the Y direction. The source electrode SE2 is provided between the two gate electrodes GE2 in the Y direction. In other words, the source electrode SE2 and the two gate electrodes GE2 are arranged in the order of the gate electrode GE2, the source electrode SE2, and the gate electrode GE2 and apart from each other in the Y direction. Note that the number of the gate electrode GE2 may be one or three or more.

The driver circuit 12 is provided above the wiring layer 22. The wiring layer 24 is provided above the driver circuit 12 and the switching element 14. The via 41 is provided between the wiring layer 24 and the driver circuit 12. The via 41 is provided between the wiring layer 24 and the switching element 14.

The dielectric layer 51 is provided above the wiring layer 22 and above the switching element 14. The multiple vias 41 are provided below the dielectric layer 51 and on the wiring layer 22. The multiple vias 41 are provided below the dielectric layer 51 and on the switching element 14. More specifically, the multiple vias 41 are provided below the dielectric layer 51 and on the source electrode SE2 in the vicinity of the front surface of the switching element 14.

The wiring layer 28 is provided above the wiring layer 23 and above the switching element 14. The multiple vias 41 are provided on the wiring layer 28.

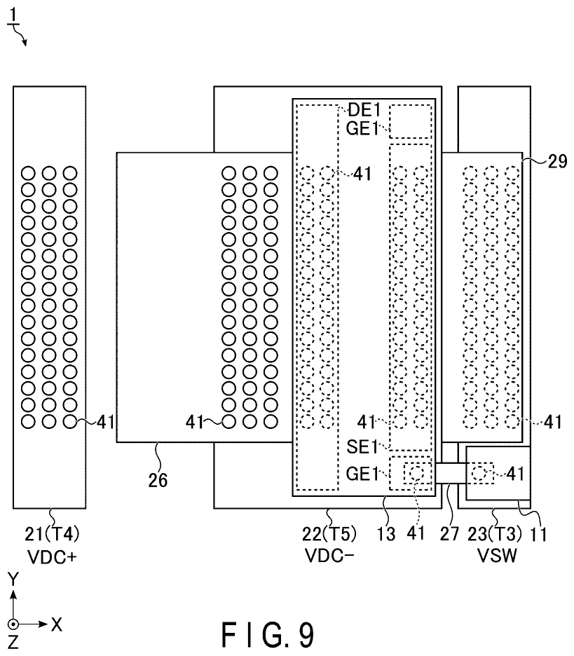

FIG. 9 is a plan view showing an example of a planar structure of the semiconductor device 1 when viewed in the downward direction from the position of a line c-c in FIGS. 5 and 6.

As shown in FIG. 9, the wiring layer 26 is provided above the wiring layer 22. The multiple vias 41 are provided on the wiring layer 26.

The wiring layer 29 is provided above the wiring layer 23. The multiple vias 41 are provided under the wiring layer 29.

The switching element 13 is provided above the wiring layers 26 and 29. Note that FIG. 9 shows the front surface of the switching element 13. The drain electrode DE1, the source electrode SE1, and two gate electrodes GE1 are provided in the vicinity of the front surface of the switching element 13.

The drain electrode DE1 is provided in the vicinity of the end portion of the front surface of the switching element 13 on the wiring layer 21 side. The source electrode SE1 and the two gate electrodes GE1 are provided in the vicinity of the end portion of the front surface of the switching element 13 on the wiring layer 23 side. In other words, the drain electrode DE1 is arranged apart from the source electrode SE1 and the two gate electrodes GE1 in the X direction.

The two gate electrodes GE1 are provided in the vicinity of both ends of the front surface of the switching element 13 in the Y direction. The source electrode SE1 is provided between the two gate electrodes GE1 in the Y direction. In other words, the source electrode SE1 and the two gate electrodes GE1 are arranged in the order of the gate electrode GE1, the source electrode SE1, and the gate electrode GE1 and apart from each other in the Y direction. Note that the number of the gate electrode GE1 may be one or three or more.

The multiple vias 41 are provided between the switching element 13 and the wiring layer 26. More specifically, the multiple vias 41 are provided between the drain electrode DE1 in the vicinity of the front surface of the switching element 13 and the wiring layer 26. The multiple vias 41 are provided between the switching element 13 and the wiring layer 29. More specifically, the multiple vias 41 are provided between the source electrode SE1 in the vicinity of the front surface of the switching element 13 and the wiring layer 29.

The driver circuit 11 is provided above the wiring layer 23. The wiring layer 27 is provided below the driver circuit 11 and the switching element 13. The via 41 is provided between the wiring layer 27 and the driver circuit 11. The via 41 is provided between the wiring layer 27 and the switching element 13.

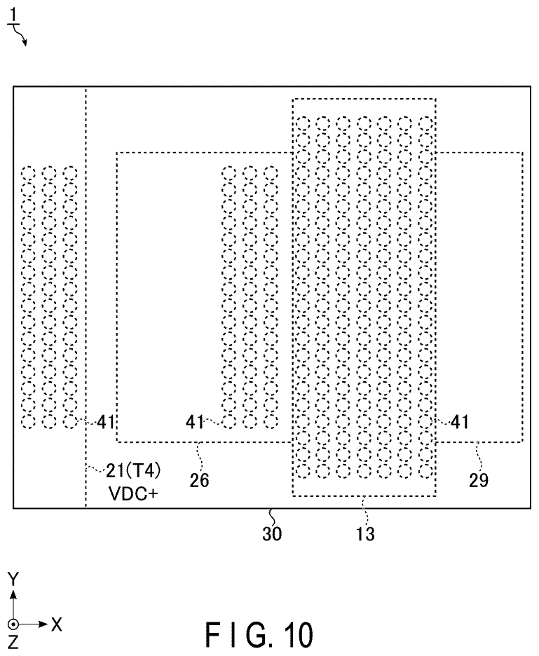

FIG. 10 is a plan view showing an example of a planar structure of the semiconductor device 1 when viewed in the downward direction from the position of a line d-d in FIGS. 5 and 6.

As shown in FIG. 10, the multiple vias 41 are provided between the wiring layer 30 and the wiring layer 21. The multiple vias 41 are provided between the wiring layer 30 and the wiring layer 26. The wiring layer 30 functions as the wiring that supplies the voltage VDC+. The switching element 13 is provided below the wiring layer 30. Note that FIG. 10 shows the back surface of the switching element 13. The multiple vias 41 provided between the wiring layer 30 and the switching element 13 are provided to dissipate the heat of the switching element 13. In other words, the wiring layer 30 also functions as the heat dissipation surface for the switching element 13.

According to the semiconductor device 1 of this embodiment, noise can be reduced.

In a power supply module having a configuration in which a snubber capacitor is connected to both ends of two switching elements connected in series, when switching ON or OFF of the two switching elements, a high frequency current flows through a loop consisting of the snubber capacitor and the two switching elements. The high frequency current may become a noise source. As the lengths of the wirings connecting the snubber capacitor and the two switching elements increase, the path of the loop increases, and the parasitic inductance of the loop increases. Therefore, to reduce the noise generated due to the high frequency current, it is desirable to shorten the path of the loop.

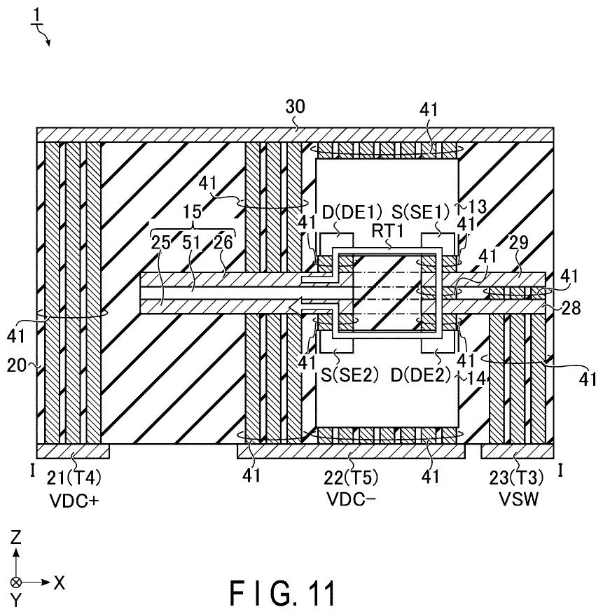

FIG. 11 is a view showing a high frequency current path of the semiconductor device 1.

As shown in FIG. 11, a high frequency current path RT1 of the semiconductor device 1 is a path from the wiring layer 26 to the wiring layer 25 through the via 41 on the wiring layer 26, the drain electrode DE1, the source electrode SE1, the via 41 under the source electrode SE1, the wiring layer 29, the via 41 under the wiring layer 29, the wiring layer 28, the via 41 under the wiring layer 28, the drain electrode DE2, the source electrode SE2, and the via 41 on the source electrode SE2.

The semiconductor device 1 according to this embodiment includes the substrate 20 incorporating the switching element 13 provided with the drain electrode DE1 and the source electrode SE1 in the vicinity of the front surface, the switching element 14 provided with the source electrode SE2 and the drain electrode DE2 in the vicinity of the front surface, and the capacitor 15.

The capacitor 15 includes the wiring layer 25 connected to the source electrode SE2, the wiring layer 26 connected to the drain electrode DE1, and the dielectric layer 51 arranged between the wiring layer 25 and the wiring layer 26. The capacitor 15 is formed between a layer where the switching element 13 is provided and a layer where the switching element 14 is provided. The source electrode SE2 is arranged to face the drain electrode DE1 in the Z direction. The drain electrode DE2 is arranged to face the source electrode SE1 in the Z direction. The drain electrode DE2 is connected to the source electrode SE1 in series.

As compared to a case where the capacitor 15 is not formed between the switching elements 13 and 14, the drain electrode DE1 and the source electrode SE2 do not face each other, and the source electrode SE1 and the drain electrode DE2 do not face each other, in this embodiment, the path between the wiring layer 26 and the drain electrode DE1 is short due to the above-described configuration. Similarly, the path between the source electrode SE1 and the drain electrode DE2 and the path between the source electrode SE2 and the wiring layer 25 are short. With this, the high frequency current path RT1 is short as compared to the case where the capacitor 15 is not formed between the switching elements 13 and 14, the drain electrode DE1 and the source electrode SE2 do not face each other, and the source electrode SE1 and the drain electrode DE2 do not face each other. Accordingly, the parasitic inductance of the loop consisting of the capacitor 15 and the switching elements 13 and 14 can be reduced. Thus, according to this embodiment, noise can be reduced. In addition, since noise is reduced, the power conversion efficiency can be improved.

The drain electrode DE1 and the source electrode SE1 are arranged to face each other in the X direction. The source electrode SE2 and the drain electrode DE2 are arranged to face each other in the X direction. Accordingly, in this embodiment, the path between the drain electrode DE1 and the source electrode SE1 and the path between the drain electrode DE2 and the source electrode SE2 are relatively short. Thus, the high frequency current path RT1 is relatively short.

The thickness of the dielectric layer 51 is smaller than the thickness of the switching element 13. The thickness of the dielectric layer 51 is also smaller than the thickness of the switching element 14. That is, the thickness of the capacitor 15 is relatively small. Accordingly, in this embodiment, the path between the wiring layer 26 and the drain electrode DE1, the path between the source electrode SE2 and the wiring layer 25, and the path between the source electrode SE1 and the drain electrode DE2 are relatively short. In addition, the thicknesses of the switching elements 13 and 14 do not affect the high frequency current path RT1. Accordingly, the high frequency current path RT1 is relatively short.

The dielectric layer 51 includes, for example, silicon or barium titanate. That is, the capacitor 15 is, for example, a silicon capacitor or a barium titanate capacitor. A relatively thin capacitor such as the silicon capacitor or the barium titanate capacitor can be formed between a layer where the switching element 13 is provided and a layer where the switching element 14 is provided in the substrate 20. Thus, the capacitor 15 can have a relatively small thickness. Hence, in this embodiment, the path between the wiring layer 26 and the drain electrode DE1, the path between the source electrode SE2 and the wiring layer 25, and the path between the source electrode SE1 and the drain electrode DE2 are relatively short. Accordingly, the high frequency current path RT1 is relatively short.

The area of the front surface of the wiring layer 26 is larger than the area of the front surface of the switching element 13. The area of the front surface of the wiring layer 25 is larger than the area of the front surface of the switching element 14. Thus, the capacitor 15 has a relatively large capacitance.

The wiring layer 26 protrudes from the switching element 13 to the wiring layer 21 side along the X direction. The wiring layer 25 protrudes from the switching element 14 to the wiring layer 21 side along the X direction. With this, each of the switching element 13 and the switching element 14 has a relatively large area. Thus, the capacitor 15 has a relatively large capacitance.

The back surface of the switching element 13 is connected to the wiring layer 30 via the multiple vias 41. With this, the heat of the switching element 13 is transferred through the multiple vias 41 and the wiring layer 30 and dissipated outside the semiconductor device 1. The back surface of the switching element 14 is connected to the wiring layer 22 via the multiple vias 41. With this, the heat of the switching element 14 is transferred through the multiple vias 41 and the wiring layer 22 and dissipated outside the semiconductor device 1.

The area of the front surface of the wiring layer 23 is smaller than the area of the front surface of the wiring layer 22. This is because, since the wiring layer 22 functions as the heat dissipation surface for the switching element 14, the wiring layer 23 need not have a function as the heat dissipation surface. Since the wiring layer 23 is connected to the wiring layers 28 and 29 included in the high frequency current path RT1, it may become a noise source. However, since the area of the front surface of the wiring layer 23 is relatively small, the noise source can be decreased.

Note that, in a case where the switching elements 13 and 14 are GaN transistors, the speed of the switching operation each of the switching elements 13 and 14 can be increased.

### 2. Second Embodiment

A semiconductor device according to the second embodiment will be described. A semiconductor device 1A according to the second embodiment includes two semiconductor devices 1, and the input/output terminal T3 is shared by the two semiconductor devices 1. Points different from the first embodiment will be described below.

### 2.1 Circuit Configuration of Semiconductor Device

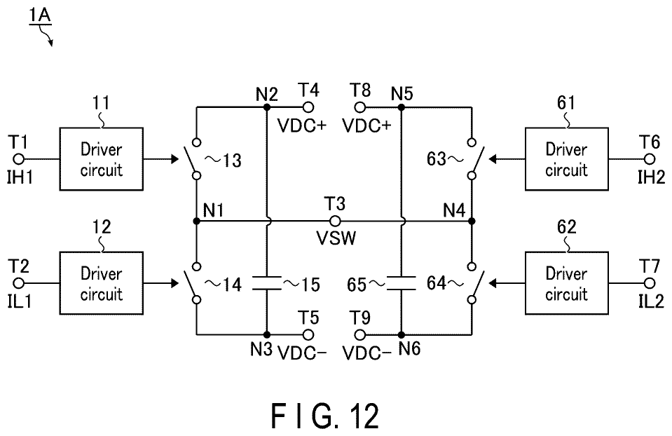

The circuit configuration of the semiconductor device 1A will be described with reference to FIG. 12. FIG. 12 is a circuit diagram showing an example of a circuit configuration of the semiconductor device 1A.

The semiconductor device 1A includes control terminals T1 and T2, driver circuits 11 and 12, input/output terminals T3 to T5, switching elements (switches) 13 and 14, the capacitor 15, control terminals T6 and T7, driver circuits 61 and 62, input/output terminals T8 and T9, switching elements (switches) 63 and 64, and a capacitor 65.

The control terminals T1 and T2, the driver circuits 11 and 12, the input/output terminals T4 and T5, the switching elements 13 and 14, and the capacitor 15 are similar to those in FIG. 1 described in the first embodiment.

The control terminal T6 is a terminal to which a control signal IH2 is externally input. The control signal IH2 is a signal for controlling the operation of the driver circuit 61. The control signal IH2 is, for example, a signal at “H” level or a signal at “L” level.

The control terminal T7 is a terminal to which a control signal IL2 is externally input. The control signal IL2 is a signal for controlling the operation of the driver circuit 62. The control signal IL2 is, for example, a signal at “H” level or a signal at “L” level.

The driver circuit 61 is a circuit that drives the switching element 63. The driver circuit 61 is connected to the control terminal T6 and the switching element 63. The driver circuit 61 turns on or off the switching element 63 based on the control signal IH2.

The driver circuit 62 is a circuit that drives the switching element 64. The driver circuit 62 is connected to the control terminal T7 and the switching element 64. The driver circuit 62 turns on or off the switching element 64 based on the control signal IL2.

The control signal IH2 is the same signal as the control signal IH1. The control signal IL2 is the same signal as the control signal IL1. Therefore, the driver circuit 61 operates in synchronization with the driver circuit 11. The driver circuit 62 operates in synchronization with the driver circuit 12. Accordingly, the driver circuits 11, 12, 61, and 62 alternately turn on or off the switching elements 13 and 63 and the switching elements 14 and 64. In other words, when one of the switching elements 13 and 63 and the switching elements 14 and 64 are in the ON state, the other are in the OFF state.

Each of the input/output terminals T3, T8, and T9 is an input terminal or an output terminal. The input/output terminal T3 is connected to nodes N1 and N4. The input/output terminal T8 is connected to a node N5. The input/output terminal T9 is connected to a node N6. A voltage VSW is applied to the node N4, that is, the input/output terminal T3. A voltage VDC+ is applied to the node N5, that is, the input/output terminal T8. A voltage VDC− is applied to the node N6, that is, the input/output terminal T9.

The switching element 63 includes a first end, a second end, and a third end. The first end of the switching element 63 is connected to the driver circuit 61. The second end of the switching element 63 is connected to the node N5. The third end of the switching element 63 is connected to the node N4. The switching element 64 includes a first end, a second end, and a third end. The first end of the switching element 64 is connected to the driver circuit 62. The second end of the switching element 64 is connected to the node N4. The third end of the switching element 64 is connected to the node N6. The switching elements 63 and 64 include, for example, at least one of an n-channel MOSFET, a p-channel MOSFET, a GaN transistor, an SiC transistor, an IGBT, and a JFET.

One electrode of the capacitor 65 is connected to the node N5. The other electrode of the capacitor 65 is connected to the node N6. In other words, the capacitor 65 is connected to both ends of the switching elements 63 and 64 connected in series. With this, the capacitor 65 functions as a snubber capacitor.

Note that, in the semiconductor device 1A, it may be configured such that the driver circuits 61 and 62 and the control terminals T6 and T7 are not mounted, and the driver circuits 11 and 12 and the control terminals T1 and T2 are shared. In this case, the control electrode of the switching element 63 is connected to the driver circuit 11. The control electrode of the switching element 64 is connected to the driver circuit 12.

Similarly to the first embodiment, depending on a configuration of a circuit (not shown) connected to the input/output terminals T3, T8, and T9, each of the input/output terminals T3, T8, and T9 serves as an input terminal or an output terminal.

A case where the switching elements 63 and 64 are n-channel MOSFETs will be described below as an example.

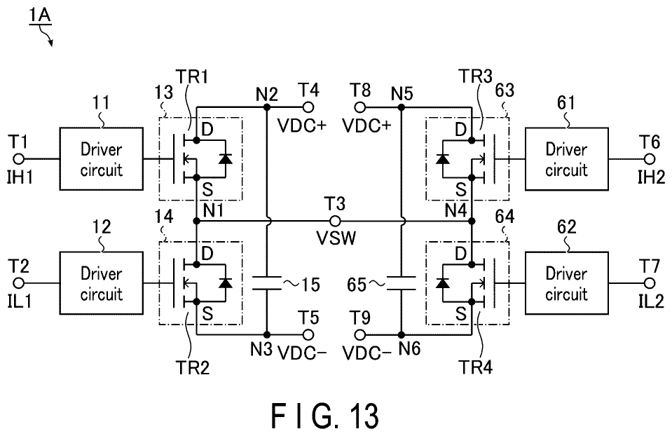

FIG. 13 is a circuit diagram showing an example of a configuration of each switching element in the semiconductor device 1A.

As shown in FIG. 13, the switching element 63 is a transistor TR3. The switching element 64 is a transistor TR4. The transistors TR3 and TR4 are n-channel MOSFETs. The transistors TR3 and TR4 are normally-off transistors.

The gate electrode (control electrode) of the switching element 63 is connected to the driver circuit 61. The drain electrode of the switching element 63 is connected to the node N5. The source electrode of the switching element 63 is connected to the node N4. The gate electrode (control electrode) of the switching element 64 is connected to the driver circuit 62. The drain electrode of the switching element 64 is connected to the node N4. The source electrode of the switching element 64 is connected to the node N6. The source electrode of the switching element 63 and the drain electrode of the switching element 64 are connected in series.

### 2.2 Structure of Semiconductor Device

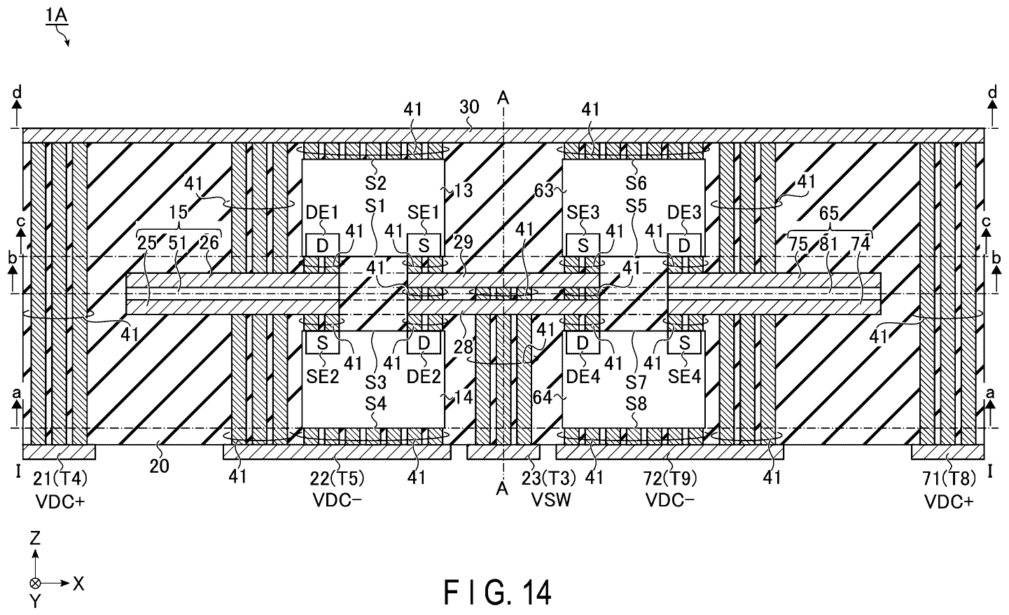

The structure of the semiconductor device 1A will be described. The semiconductor 1A has a structure combining two semiconductor devices 1. FIG. 14 is a sectional view showing an example of a sectional structure of the semiconductor device 1A taken along the same line as the line I-I in FIG. 4 described in the first embodiment.

As shown in FIG. 14, in the semiconductor device 1A, with a line (to be referred to as a “line A-A” hereinafter) extending from the center of the front surface of the wiring layer 23 along the Z direction as the boundary, the left structure along the X-axis has the same structure as the semiconductor device 1, and the right structure along the X-axis has a structure obtained by rotating the semiconductor device 1 by 180° around the line A-A as the rotation axis. A wiring layer 71 corresponds to the wiring layer 21. A wiring layer 72 corresponds to the wiring layer 22. The switching element 63 corresponds to the switching element 13. The switching element 64 corresponds to the switching element 14. A wiring layer 74 corresponds to the wiring layer 25. A dielectric layer 81 corresponds to a dielectric layer 51. A wiring layer 75 corresponds to the wiring layer 26. The capacitor 65 corresponds to the capacitor 15.

The wiring layers 71 and 72 are provided on the back surface of the substrate 20. The wiring layers 23, 71, and 72 are arranged apart from each other in the X direction. The wiring layer 71 corresponds to the input/output terminal T8. The voltage VDC+ is applied to the wiring layer 71. The wiring layer 72 corresponds to the input/output terminal T9. The voltage VDC− is applied to the wiring layer 72.

The switching element 63 includes a surface S5 and a surface S6 facing the surface S5. Hereinafter, the surface S5 will also be referred to as “the front surface of the switching element 63”, and the surface S6 will also be referred to as “the back surface of the switching element 63”. A drain electrode DE3 and a source electrode SE3 are provided in the vicinity of the front surface of the switching element 63. The multiple vias 41 are provided between the switching element 63 and the wiring layer 30.

The switching element 64 includes a surface S7 and a surface S8 facing the surface S7. Hereinafter, the surface S7 will also be referred to as “the front surface of the switching element 64”, and the surface S8 will also be referred to as “the back surface of the switching element 64”. A source electrode SE4 and a drain electrode DE4 are provided in the vicinity of the front surface of the switching element 64. The multiple vias 41 are provided between the switching element 64 and the wiring layer 72.

The wiring layer 74 is provided above the switching element 64. The multiple vias 41 are provided between the end portion of the lower surface of the wiring layer 74 on the switching element 64 side and the source electrode SE4 of the switching element 64. In other words, the end portion of the lower surface of the wiring layer 74 on the switching element 64 side is in contact with the multiple vias 41. The source electrode SE4 of the switching element 64 is in contact with the multiple vias 41. That is, the wiring layer 74 is connected to the source electrode SE4 of the switching element 64 via the multiple vias 41. The multiple vias 41 are provided between the wiring layer 74 and the wiring layer 72. The wiring layer 74 functions as a wiring that supplies the voltage VDC−. The wiring layer 74 also functions as the other electrode of the capacitor 65.

The dielectric layer 81 is provided on the wiring layer 74.

The wiring layer 75 is provided on the dielectric layer 81 and below the switching element 63. The multiple vias 41 are provided between the end portion of the upper surface of the wiring layer 75 on the switching element 63 side and the drain electrode DE3 of the switching element 63. In other words, the end portion of the upper surface of the wiring layer 75 on the switching element 63 side is in contact with the multiple vias 41. The drain electrode DE3 of the switching element 63 is in contact with the multiple vias 41. That is, the wiring layer 75 is connected to the drain electrode DE3 of the switching element 63 via the multiple vias 41. The multiple vias 41 are provided between the wiring layer 75 and the wiring layer 30. The wiring layer 75 functions as a wiring that supplies the voltage VDC+. The wiring layer 75 also functions as one electrode of the capacitor 65.

The multiple vias 41 are provided between the wiring layer 71 and the wiring layer 30.

The wiring layer 71 is connected to the wiring layer 75 via the multiple vias 41, the wiring layer 30, and the multiple vias 41. The wiring layer 72 is connected to the wiring layer 74 via the multiple vias 41. The wiring layer 23 is connected to the source electrode SE3 of the switching element 63 via the multiple vias 41, the wiring layer 28, the multiple vias 41, the wiring layer 29, and the multiple vias 41. The wiring layer 23 is also connected to the drain electrode DE4 of the switching element 64 via the multiple vias 41, the wiring layer 28, and the multiple vias 41.

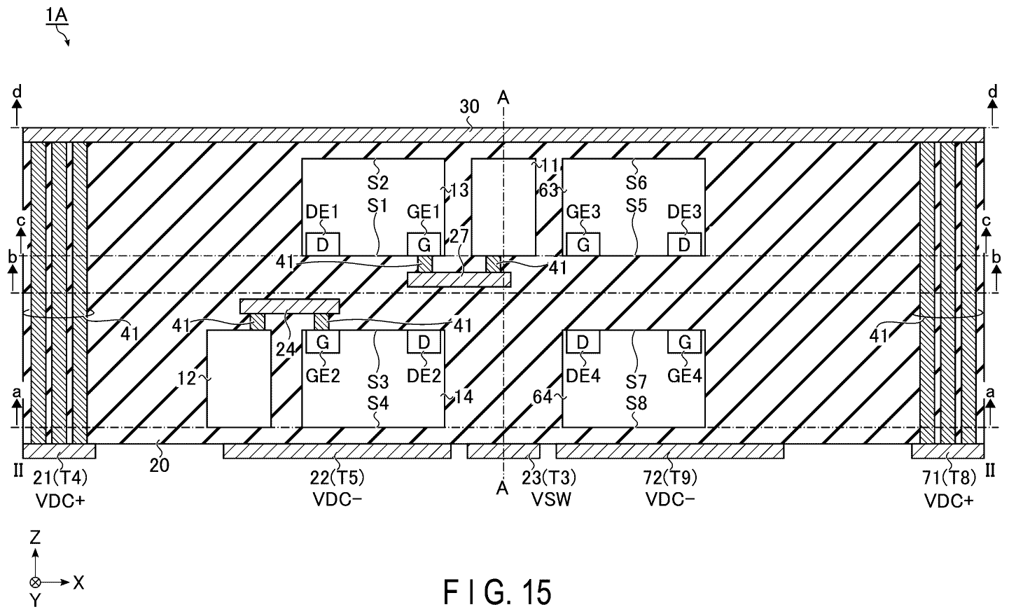

FIG. 15 is a sectional view showing an example of a sectional structure of the semiconductor device 1A taken along the same line as the line II-II in FIG. 4 described in the first embodiment.

As shown in FIG. 15, in the semiconductor device 1A, the sectional structure along the same line as the line II-II in FIG. 4 is different between the left structure along the X-axis and the right structure along the X-axis with the line A-A as the boundary.

A gate electrode GE3 is provided in the vicinity of the front surface of the switching element 63. A gate electrode GE4 is provided in the vicinity of the front surface of the switching element 64.

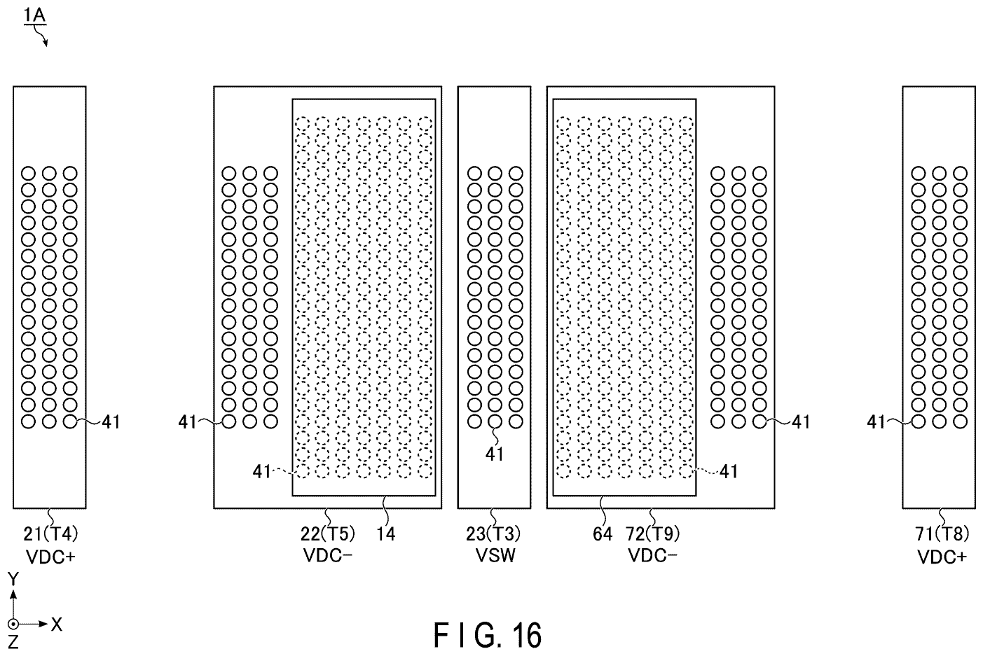

FIG. 16 is a plan view showing an example of a planar structure of the semiconductor device 1A when viewed in the downward direction from the position of a line a-a in FIGS. 14 and 15.

As shown in FIG. 16, the multiple vias 41 are provided on the wiring layer 71. The wiring layer 71 functions as an external connection terminal for the voltage VDC+.

The multiple vias 41 are provided on the wiring layer 72. The wiring layer 72 functions as an external connection terminal for the voltage VDC−. The switching element 64 is provided above the wiring layer 72. Note that FIG. 16 shows the back surface of the switching element 64. The multiple vias 41 provided between the wiring layer 72 and the switching element 64 are provided to dissipate the heat of the switching element 64. In other words, the wiring layer 72 also functions as the heat dissipation surface for the switching element 64.

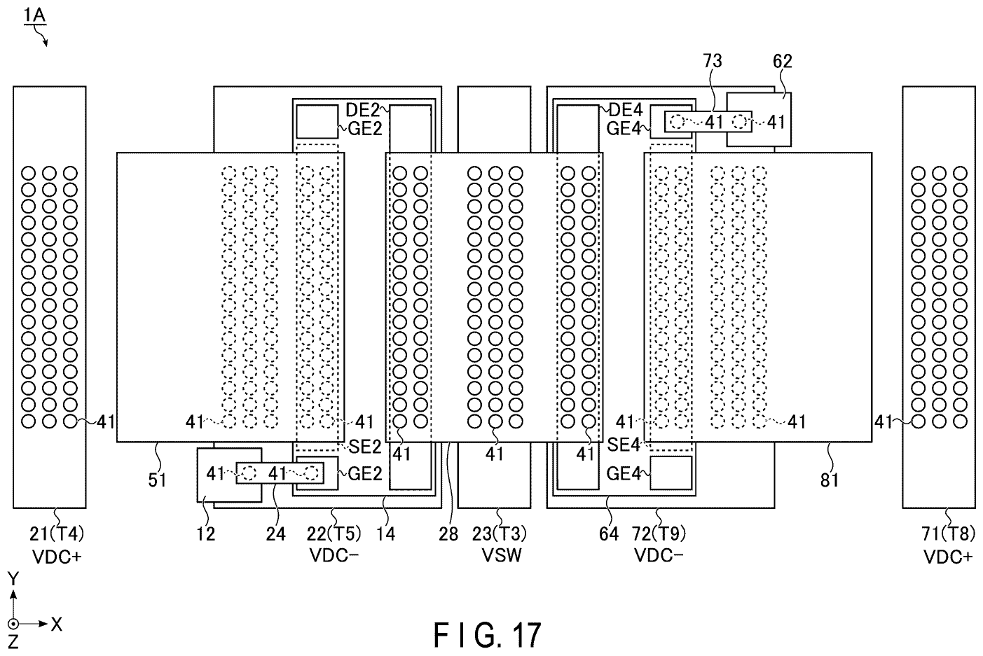

FIG. 17 is a plan view showing an example of a planar structure of the semiconductor device 1A when viewed in the downward direction from the position of a line b-b in FIGS. 14 and 15.

As shown in FIG. 17, the switching element 64 is provided above the wiring layer 72. Note that FIG. 17 shows the front surface of the switching element 64. The drain electrode DE4, the source electrode SE4, and two gate electrodes GE4 are provided in the vicinity of the front surface of the switching element 64.

The drain electrode DE4 is provided in the vicinity of the end portion of front surface of the switching element 64 on the wiring layer 23 side. The source electrode SE4 and the two gate electrodes GE4 are provided in the vicinity of the end portion of the front surface of the switching element 64 on the wiring layer 71 side. In other words, the drain electrode DE4 is arranged apart from the source electrode SE4 and the two gate electrodes GE4 in the X direction.

The two gate electrodes GE4 are provided in the vicinity of both ends of the front surface of the switching element 64 in the Y direction. The source electrode SE4 is provided between the two gate electrodes GE4 in the Y direction. In other words, the source electrode SE4 and the two gate electrodes GE4 are arranged in the order of the gate electrode GE4, the source electrode SE4, and the gate electrode GE4 and apart from each other in the Y direction. Note that the number of the gate electrode GE4 may be one or three or more.

The driver circuit 62 is provided above the wiring layer 72. The driver circuit 62 corresponds to the driver circuit 12. A wiring layer 73 is provided above the driver circuit 62 and the switching element 64. The wiring layer 73 corresponds to the wiring layer 24. The via 41 is provided between the wiring layer 73 and the driver circuit 62. The via 41 is provided between the wiring layer 73 and the switching element 64.

The dielectric layer 81 is provided above the wiring layer 72 and above the switching element 64. The multiple vias 41 are provided below the dielectric layer 81 and on the wiring layer 72. The multiple vias 41 are provided below the dielectric layer 81 and on the switching element 64. More specifically, the multiple vias 41 are provided below the dielectric layer 81 and on the source electrode SE4 in the vicinity of the front surface of the switching element 64.

The wiring layer 28 is provided above the wiring layer 23 and above the switching element 64. The multiple vias 41 are provided on the wiring layer 28.

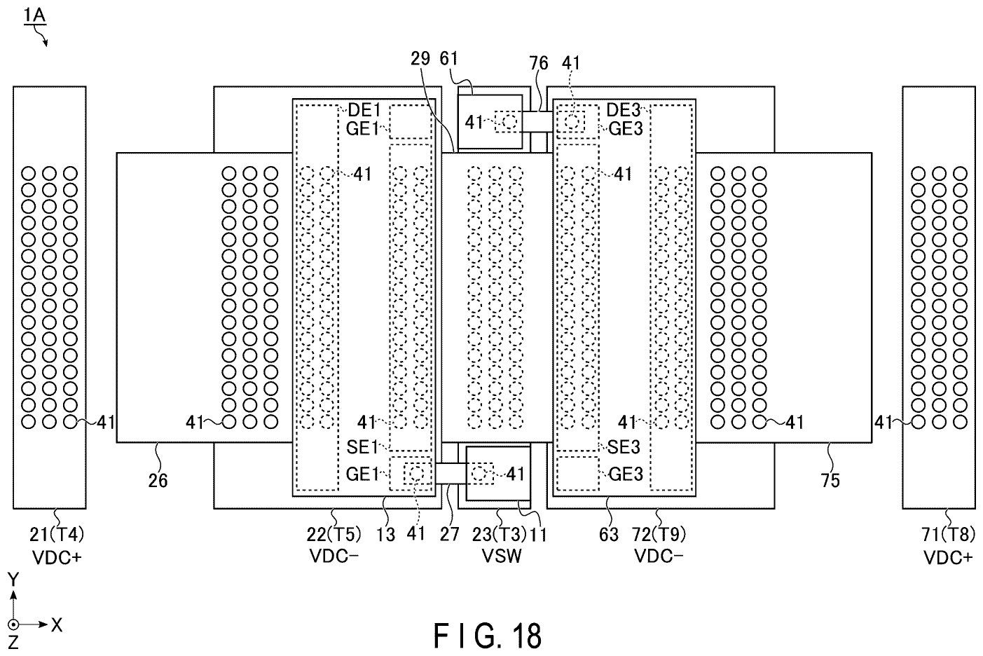

FIG. 18 is a plan view showing an example of a planar structure of the semiconductor device 1A when viewed in the downward direction from the position of a line c-c in FIGS. 14 and 15.

As shown in FIG. 18, the wiring layer 75 is provided above the wiring layer 72. The multiple vias 41 are provided on the wiring layer 75.

The wiring layer 29 is provided above the wiring layer 23. The multiple vias 41 are provided under the wiring layer 29.

The switching element 63 is provided above the wiring layers 75 and 29. Note that FIG. 18 shows the front surface of the switching element 63. The drain electrode DE3, the source electrode SE3, and two gate electrodes GE3 are provided in the vicinity of the front surface of the switching element 63.

The drain electrode DE3 is provided in the vicinity of the end portion of the front surface of the switching element 63 on the wiring layer 71 side. The source electrode SE3 and the two gate electrodes GE3 are provided in the vicinity of the end portion of the front surface of the switching element 63 on the wiring layer 23 side. In other words, the drain electrode DE3 is arranged apart from the source electrode SE3 and the two gate electrodes GE3 in the X direction.

The two gate electrodes GE3 are provided in the vicinity of both ends of the front surface of the switching element 63 in the Y direction. The source electrode SE3 is provided between the two gate electrodes GE3 in the Y direction. In other words, the source electrode SE3 and the two gate electrodes GE3 are arranged in the order of the gate electrode GE3, the source electrode SE3, and the gate electrode GE3 and apart from each other in the Y direction. Note that the number of the gate electrode GE3 may be one or three or more.

The multiple vias 41 are provided between the switching element 63 and the wiring layer 75. More specifically, the multiple vias 41 are provided between the drain electrode DE3 in the vicinity of the front surface of the switching element 63 and the wiring layer 75. The multiple vias 41 are provided between the switching element 63 and the wiring layer 29. More specifically, the multiple vias 41 are provided between the source electrode SE3 in the vicinity of the front surface of the switching element 63 and the wiring layer 29.

The driver circuit 61 is provided above the wiring layer 23. The driver circuit 61 corresponds to the driver circuit 11. A wiring layer 76 is provided below the driver circuit 61 and the switching element 63. The wiring layer 76 corresponds to the wiring layer 27. The via 41 is provided between the wiring layer 76 and the driver circuit 61. The via 41 is provided between the wiring layer 76 and the switching element 63.

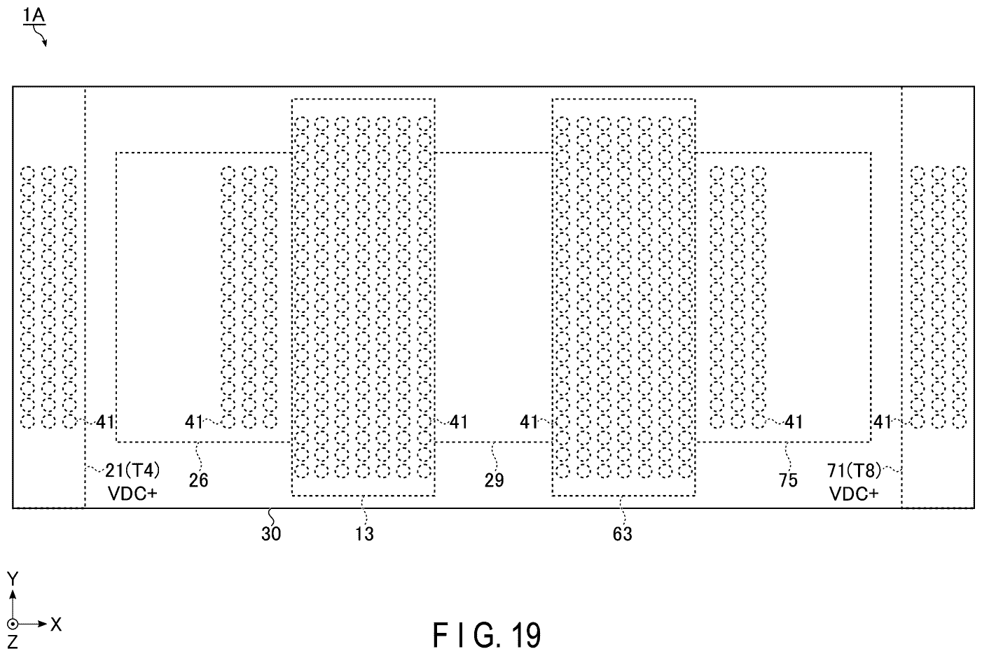

FIG. 19 is a plan view showing an example of a planar structure of the semiconductor device 1A when viewed in the downward direction from the position of a line d-d in FIGS. 14 and 15.

As shown in FIG. 19, the multiple vias 41 are provided between the wiring layer 30 and the wiring layer 71. The multiple vias 41 are provided between the wiring layer 30 and the wiring layer 75. The switching element 63 is provided below the wiring layer 30. Note that FIG. 19 shows the back surface of the switching element 63. The multiple vias 41 provided between the wiring layer 30 and the switching element 63 are provided to dissipate the heat of the switching element 63. In other words, the wiring layer 30 also functions as the heat dissipation surface for the switching element 63.

According to the semiconductor device 1A of this embodiment, noise can be reduced.

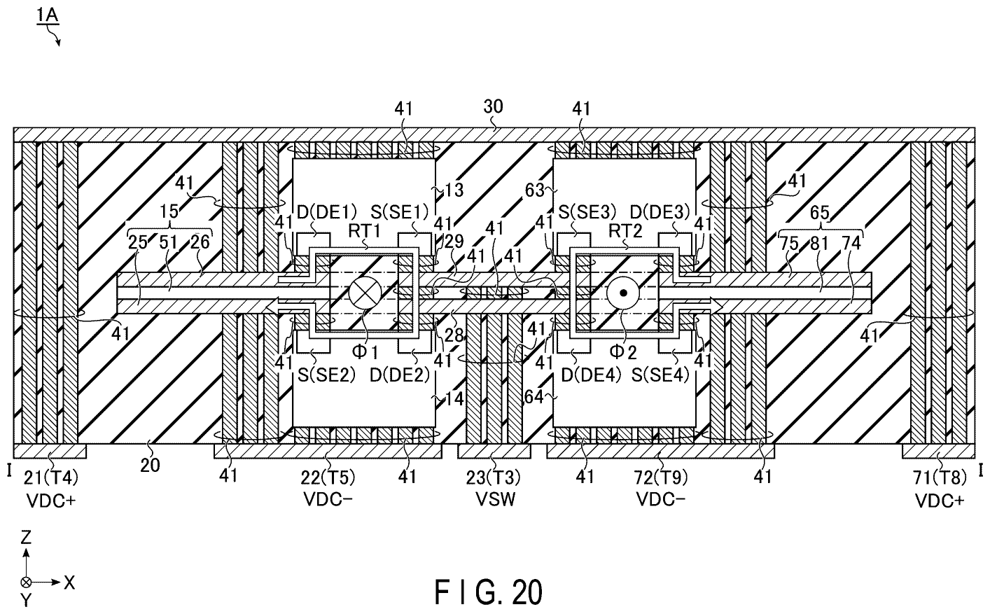

FIG. 20 is a view showing high frequency current paths of the semiconductor device 1A and a magnetic flux generated by a high frequency current.

As shown in FIG. 20, the high frequency current paths of the semiconductor device 1A includes the path (to be referred to as a “first path RT1” hereinafter) in FIG. 11 described in the first embodiment.

The semiconductor device 1A also includes a path (to be referred to as a “second path RT2” hereinafter) from the wiring layer 75 to the wiring layer 74 through the via 41 on the wiring layer 75, the drain electrode DE3, the source electrode SE3, the via 41 under the source electrode SE3, the wiring layer 29, the via 41 under the wiring layer 29, the wiring layer 28, the via 41 under the wiring layer 28, the drain electrode DE4, the source electrode SE4, and the via 41 on the source electrode SE4.

The semiconductor device 1A according to this embodiment includes the semiconductor device 1 described in the first embodiment.

The substrate 20 incorporates the switching element 63 provided with the drain electrode DE3 and the source electrode SE3 in the vicinity of the front surface, the switching element 64 provided with the source electrode SE4 and the drain electrode DE4 in the vicinity of the front surface, and the capacitor 65.

The capacitor 65 includes the wiring layer 74 connected to the source electrode SE4, the wiring layer 75 connected to the drain electrode DE3, and the dielectric layer 81 arranged between the wiring layer 74 and the wiring layer 75. The capacitor 65 is formed between a layer where the switching element 63 is provided and a layer where the switching element 64 is provided. The source electrode SE4 is arranged to face the drain electrode DE3 in the Z direction. The drain electrode DE4 is arranged to face the source electrode SE3 in the Z direction. The drain electrode DE4 is connected to the source electrode SE3 in series.

Due to the above-described configuration, in this embodiment, the high frequency current path is short in each of the first path RT1 and the second path RT2, similarly to the first embodiment. Thus, this embodiment has an effect similar to that of the first embodiment.

Further, the wiring layer 25 is connected to the wiring layer 22 that supplies the voltage VDC−. The wiring layer 26 is connected to the wiring layer 21 that supplies the voltage VDC+. The source electrode SE1 and the drain electrode DE2 are connected to the wiring layer 23 that supplies the voltage VSW in a range of the voltage VDC− or more to the voltage VDC+ or less. The wiring layer 74 is connected to the wiring layer 72 that supplies the voltage VDC−. The wiring layer 75 is connected to the wiring layer 71 that supplies the voltage VDC+. The source electrode SE3 and the drain electrode DE4 are connected to the wiring layer 23.

The switching elements 63 and 64 and the capacitor 65 (the wiring layers 74 and 75 and the dielectric layer 81) are arranged at positions obtained by rotating the switching elements 13 and 14 and the capacitor 15 (the wiring layers 25 and 26 and the dielectric layer 51) by 180° around the line A-A as the rotation axis. The wiring layers 71 and 72 are arranged at positions obtained by rotating the wiring layers 21 and 22 by 180° around the line A-A as the rotation axis.

Due to the above-described configuration, as shown in FIG. 20, in this embodiment, the direction (the direction from the front side to the back side of the drawing surface) of a magnetic flux Φ1 generated by the high frequency current flowing through the first path RT1 is opposite to the direction (the direction from the back side to the front side of the drawing surface) of a magnetic flux Φ2 generated by the high frequency current flowing through the second path RT2. Therefore, the magnetic fluxes respectively generated in the two paths RT1 and RT2 cancel each other. Thus, noise discharged to the outside due to the generation of the magnetic flux can be suppressed. Hence, according to this embodiment, noise can be reduced. In addition, since noise is reduced, the power conversion efficiency can be improved.

### 3. Third Embodiment

A semiconductor device according to the third embodiment will be described. A semiconductor device 1B according to the third embodiment has a configuration in which the switching elements 13 and 14 of the semiconductor device 1 are replaced with normally-on switching elements, and normally-off switching elements and driver circuits (to be referred to as “ON-off driver circuits” hereinafter) for implementing Quasi normally-off are added to the semiconductor device 1. Points different from the first embodiment will be described below.

### 3.1 Circuit Configuration of Semiconductor Device

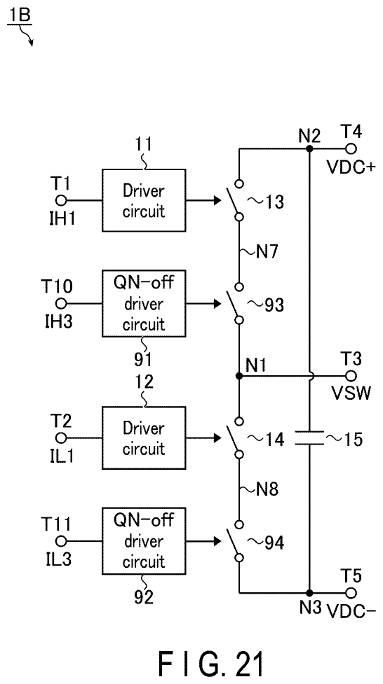

The circuit configuration of the semiconductor device 1B will be described with reference to FIG. 21. FIG. 21 is a circuit diagram showing an example of a circuit configuration of the semiconductor device 1B.

The semiconductor device 1B includes control terminals T1 and T2, driver circuits 11 and 12, input/output terminals T3 to T5, switching elements (switches) 13 and 14, and the capacitor 15. The semiconductor device 1B also includes control terminals T10 and T11, QN-off driver circuits 91 and 92, and switching elements (switches) 93 and 94.

The control terminals T1 and T2, the input/output terminals T3 to T5, and the capacitor 15 are similar to those in FIG. 1 described in the first embodiment.

The third end of the switching element 13 is connected to a node N7. The third end of the switching element 14 is connected to a node N8. The switching elements 13 and 14 include, for example, at least one of an n-channel MOSFET, a p-channel MOSFET, a GaN transistor, an SiC transistor, an IGBT, and a JFET. The switching elements 13 and 14 are normally-on switching elements.

The control terminal T10 is a terminal to which a control signal IH3 is externally input. The control signal IH3 is a signal for controlling the operation of the QN-off driver circuit 91. The control signal IH3 is, for example, a signal at “H” level or a signal at “L” level.

The control terminal T11 is a terminal to which a control signal IL3 is externally input. The control signal IL3 is a signal for controlling the operation of the QN-off driver circuit 92. The control signal IL3 is, for example, a signal at “H” level or a signal at “L” level.

The QN-off driver circuit 91 is a circuit that drives the switching element 93. The QN-off driver circuit 91 is connected to the control terminal T10 and the switching element 93. The ON-off driver circuit 91 turns on or off the switching element 93 based on the control signal IH3.

The ON-off driver circuit 92 is a circuit that drives the switching element 94. The ON-off driver circuit 92 is connected to the control terminal T11 and the switching element 94. The QN-off driver circuit 92 turns on or off the switching element 94 based on the control signal IL3.

The driver circuit 11 turns on the switching element 13 in accordance with an ON request signal for the switching element 13 by the control signal IH1. The driver circuit 11 turns off the switching element 13 in accordance with an OFF request signal for the switching element 13 by the control signal IH1.

The driver circuit 12 turns on the switching element 14 in accordance with an ON request signal for the switching element 14 by the control signal IL1. The driver circuit 12 turns off the switching element 14 in accordance with an OFF request signal for the switching element 14 by the control signal IL1.

However, when turning on or off the power supply of the entire system including the semiconductor device 1B, that is, when the power supply is in the indeterminate state, the switching elements 13 and 14 may be turned on unintentionally.

Therefore, when the power supply is in the indeterminate state, the control signals IH3 and IL3 are controlled to turn off the switching elements 93 and 94. With this, the High-side switching elements including the switching elements 13 and 93 and the Low-side switching elements including the switching elements 14 and 94 are all set in the OFF state. On the other hand, when the power supply is in the steady state, the control signals IH3 and IL3 are controlled to turn on the switching elements 93 and 94. The control signals IH1 and IL are controlled to alternately turn on or off the switching elements 13 and 14. With this, the High-side switching elements including the switching elements 13 and 93 and the Low-side switching elements including the switching elements 14 and 94 are alternately set in the ON state or the OFF state. In this manner, “quasi normally-off” is implemented. Thus, by alternately driving the High-side switching elements and the Low-side switching elements, power conversion and control are performed.

The switching element 93 includes a first end, a second end, and a third end. The first end of the switching element 93 is connected to the ON-off driver circuit 91. The second end of the switching element 93 is connected to the node N7. The third end of the switching element 93 is connected to the node N1. The switching element 94 includes a first end, a second end, and a third end. The first end of the switching element 94 is connected to the QN-off driver circuit 92. The second end of the switching element 94 is connected to the node N8. The third end of the switching element 94 is connected to the node N3. The switching elements 93 and 94 include, for example, at least one of an n-channel MOSFET and a p-channel MOSFET. The switching elements 93 and 94 are normally-off switching elements.

A case where the switching elements 13 and 14 are n-channel MOSFETs and the switching elements 93 and 94 are p-channel MOSFETs will be described below as an example.

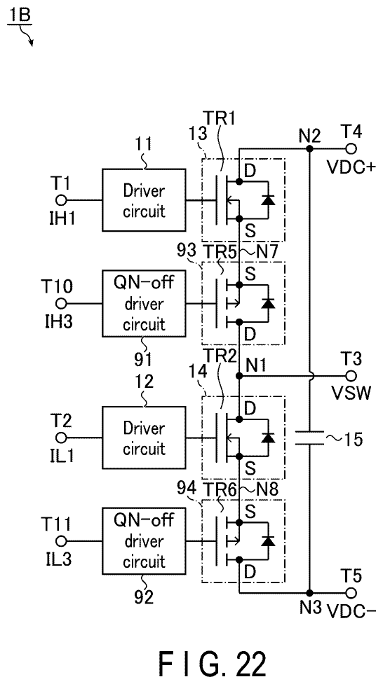

FIG. 22 is a circuit diagram showing an example of a configuration of each switching element in the semiconductor device 1B.

As shown in FIG. 22, the switching element 13 is the transistor TR1. The switching element 14 is the transistor TR2. The transistors TR1 and TR2 are n-channel MOSFETs. The transistors TR1 and TR2 are normally-on transistors.

The source electrode of the switching element 13 is connected to the node N7. The source electrode of the switching element 14 is connected to the node N8.

The switching element 93 is a transistor TR5. The switching element 94 is a transistor TR6. The transistors TR5 and TR6 are p-channel MOSFETs. The transistors TR5 and TR6 are normally-off transistors.

The gate electrode (control electrode) of the switching element 93 is connected to the ON-off driver circuit 91. The drain electrode of the switching element 93 is connected to the node N1. The source electrode of the switching element 93 is connected to the node N7. The gate electrode (control electrode) of the switching element 94 is connected to the ON-off driver circuit 92. The drain electrode of the switching element 94 is connected to the node N3. The source electrode of the switching element 94 is connected to the node N8.

The source electrode of the switching element 13 and the source electrode of the switching element 93 are connected in series. The drain electrode of the switching element 93 and the drain electrode of the switching element 14 are connected in series. The source electrode of the switching element 14 and the source electrode of the switching element 94 are connected in series.

### 3.2 Structure of Semiconductor Device

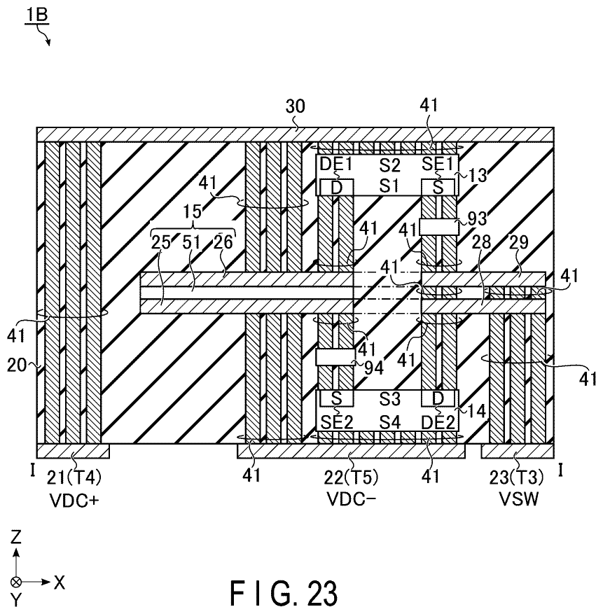

The structure of the semiconductor device 1B will be described. The semiconductor device 1B has a structure in which the switching element 93 is provided between the wiring layer 29 and the switching element 13 of the semiconductor device 1, and the QN-off driver circuit 91 connected to the switching element 93 is provided. Further, the semiconductor device 1B has the structure in which the switching element 94 is provided between the wiring layer 25 and the switching element 14 of the semiconductor device 1, and the QN-off driver circuit 92 connected to the switching element 94 is provided. FIG. 23 is a sectional view showing an example of a sectional structure of the semiconductor device 1B taken along the same line as the line I-I in FIG. 4 described in the first embodiment.

The switching element 93 is provided above the wiring layer 29. The drain electrode (not shown) of the switching element 93 is connected to the wiring layer 29 via the multiple vias 41. The switching element 13 is provided above the switching element 93. The source electrode (not shown) of the switching element 93 is connected to the source electrode SE1 of the switching element 13 via the multiple vias 41. The drain electrode of the switching element 93 is provided, for example, on the surface (the surface facing the wiring layer 29 in the Z direction) of the switching element 93. The source electrode of the switching element 93 is provided, for example, on the surface (the surface facing the source electrode SE1 in the Z direction) of the switching element 93. The drain electrode DE2 of the switching element 14 is connected to the switching element 93 in series.

The switching element 94 is provided below the wiring layer 25. The drain electrode (not shown) of the switching element 94 is connected to the wiring layer 25 via the multiple vias 41. The switching element 14 is provided below the switching element 94. The source electrode (not shown) of the switching element 94 is connected to the source electrode SE2 of the switching element 14 via the multiple vias 41. The drain electrode of the switching element 94 is provided, for example, on the surface (the surface facing the wiring layer 25 in the Z direction) of the switching element 94. The source electrode of the switching element 94 is provided, for example, on the surface (the surface facing the source electrode SE2 in the Z direction) of the switching element 94.

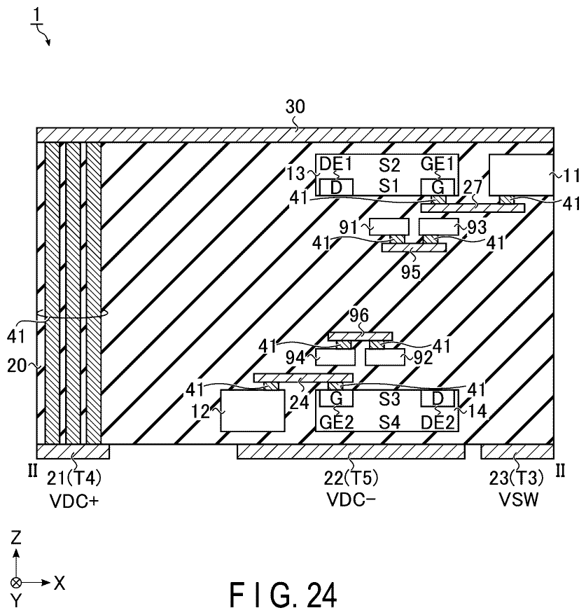

FIG. 24 is a sectional view showing an example of a sectional structure of the semiconductor device 1B taken along the same line as the line II-II in FIG. 4.

As shown in FIG. 24, the gate electrode GE1 is provided in the vicinity of the front surface of the switching element 13. The gate electrode GE2 is provided in the vicinity of the front surface of the switching element 14.

A wiring layer 95 is provided below the switching element 93. The switching element 93 is connected to the wiring layer 95 via the via 41. The ON-off driver circuit 91 is provided above the wiring layer 95 and below the switching element 13. The QN-off driver circuit 91 is connected to the wiring layer 95 via the via 41.

A wiring layer 96 is provided above the switching element 94. The switching element 94 is connected to the wiring layer 96 via the via 41. The ON-off driver circuit 92 is provided below the wiring layer 96 and above the switching element 14. The ON-off driver circuit 92 is connected to the wiring layer 96 via a via 41.

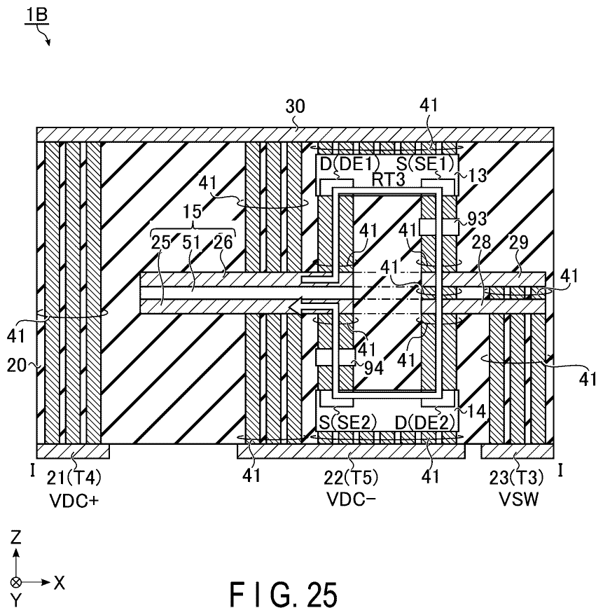

FIG. 25 is a view showing a high frequency current path of the semiconductor device 1B.

As shown in FIG. 25, a high frequency current path RT3 of the semiconductor device 1B is a path from the wiring layer 26 to the wiring layer 25 through the via 41 on the wiring layer 26, the drain electrode DE1, the source electrode SE1, the via 41 under the source electrode SE1, the switching element 93, the via 41 under the switching element 93, the wiring layer 29, the via 41 under the wiring layer 29, the wiring layer 28, the via 41 under the wiring layer 28, the drain electrode DE2, the source electrode SE2, the via 41 on the source electrode SE2, the switching element 94, and the via 41 on the switching element 94.

The semiconductor device 1B according to this embodiment includes the substrate 20 incorporating the switching element 13 provided with the drain electrode DE1 and the source electrode SE1 in the vicinity of the front surface, the switching element 14 provided with the source electrode SE2 and the drain electrode DE2 in the vicinity of the front surface, the switching elements 93 and 94, and the capacitor 15.

The switching element 93 is provided between the source electrode SE1 and the drain electrode DE2. The switching element 94 is provided between the drain electrode DE1 and the source electrode SE2. More specifically, the switching element 93 is provided between the wiring layer 29 and the switching element 13. The switching element 94 is provided between the wiring layer 25 and the switching element 14.

Due to the above-described configuration, in this embodiment, the length of the high frequency current path RT3 can be equivalent to the length of the high frequency current path RT1 described in the first embodiment. Hence, the parasitic inductance of the loop consisting of the capacitor 15 and the switching elements 13, 14, 93, and 94 can be reduced. Thus, according to this embodiment, noise can be reduced and the power conversion efficiency can be improved, as in the first embodiment.

### 4. Fourth Embodiment

A semiconductor device according to the fourth embodiment will be described. A semiconductor device 1C according to the fourth embodiment has a configuration in which the switching elements 13, 14, 63, and 64 of the semiconductor device 1A are replaced with normally-on switching elements, and normally-off switching elements and QN-off driver circuits are added to the semiconductor device 1A. Points different from the second embodiment will be described below.

### 4.1 Circuit Configuration of Semiconductor Device

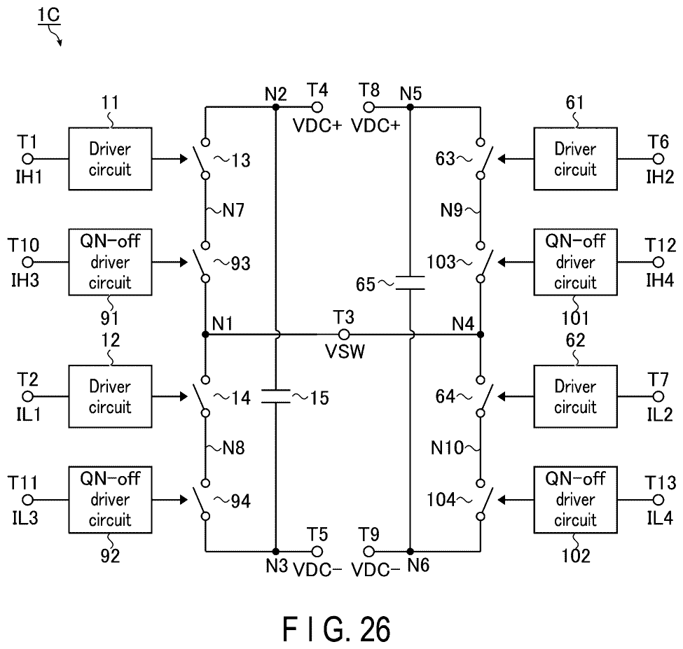

The circuit configuration of the semiconductor device 1C will be described with reference to FIG. 26. FIG. 26 is a circuit diagram showing an example of a circuit configuration of the semiconductor device 1C.

The semiconductor device 1C includes control terminals T1 and T2, driver circuits 11 and 12, input/output terminals T3 to T5, switching elements (switches) 13 and 14, the capacitor 15, control terminals T6 and T7, driver circuits 61 and 62, input/output terminals T8 and T9, switching elements (switches) 63 and 64, and the capacitor 65. The semiconductor device 1C also includes control terminals T10 and T11, QN-off driver circuits 91 and 92, switching elements (switches) 93 and 94, control terminals T12 and T13, QN-off driver circuits 101 and 102, and switching elements (switches) 103 and 104.

The control terminals T1 and T2, the input/output terminals T3 to T5, the capacitor 15, the control terminals T6 and T7, the input/output terminals T8 and T9, and the capacitor 65 are similar to those in FIG. 12 described in the second embodiment.

The driver circuits 11 and 12, the switching elements 13 and 14, the control terminals T10 and T11, the QN-off driver circuits 91 and 92, and the switching elements 93 and 94 are similar to those in FIG. 21 described in the third embodiment.

The third end of the switching element 63 is connected to a node N9. The third end of the switching element 64 is connected to a node N10. The switching elements 63 and 64 include, for example, at least one of an n-channel MOSFET, a p-channel MOSFET, a GaN transistor, an SiC transistor, an IGBT, and a JFET. The switching elements 63 and 64 are normally-on switching elements.

The control terminal T12 is a terminal to which a control signal IH4 is externally input. The control signal IH4 is a signal for controlling the operation of the QN-off driver circuit 101. The control signal IH4 is, for example, a signal at “H” level or a signal at “L” level.

The control terminal T13 is a terminal to which a control signal IL4 is externally input. The control signal IL4 is a signal for controlling the operation of the ON-off driver circuit 102. The control signal IL4 is, for example, a signal at “H” level or a signal at “L” level.

The QN-off driver circuit 101 is a circuit that drives the switching element 103. The ON-off driver circuit 101 is connected to the control terminal T12 and the switching element 103. The QN-off driver circuit 101 turns on or off the switching element 103 based on the control signal IH4.

The QN-off driver circuit 102 is a circuit that drives the switching element 104. The ON-off driver circuit 102 is connected to the control terminal T13 and the switching element 104. The ON-off driver circuit 102 turns on or off the switching element 104 based on the control signal IL4.

The driver circuit 61 operates similarly to the driver circuit 11. The driver circuit 62 operates similarly to the driver circuit 12. The ON-off driver circuit 101 operates similarly to the ON-off driver circuit 91. The QN-off driver circuit 102 operates similarly to the QN-off driver circuit 92. With this, when the power supply is in the indeterminate state, the High-side switching elements including the switching elements 63 and 103 and the Low-side switching elements including the switching elements 64 and 104 are all set in the OFF state. On the other hand, when the power supply is in the steady state, the High-side switching elements including the switching elements 63 and 103 and the Low-side switching elements including the switching elements 64 and 104 are alternately set in the ON state or the OFF state.

The control signal IH2 is the same signal as the control signal IH1. The control signal IL2 is the same signal as the control signal IL1. Therefore, the driver circuit 61 operates in synchronization with the driver circuit 11. The driver circuit 62 operates in synchronization with the driver circuit 12.

The control signal IH4 is the same signal as the control signal IH3. The control signal IL4 is the same signal as the control signal IL3. Therefore, the QN-off driver circuit 101 operates in synchronization with the ON-off driver circuit 91. The ON-off driver circuit 102 operates in synchronization with the ON-off driver circuit 92.

The switching element 103 includes a first end, a second end, and a third end. The first end of the switching element 103 is connected to the QN-off driver circuit 101. The second end of the switching element 103 is connected to the node N9. The third end of the switching element 103 is connected to the node N4. The switching element 104 includes a first end, a second end, and a third end. The first end of the switching element 104 is connected to the QN-off driver circuit 102. The second end of the switching element 104 is connected to the node N10. The third end of the switching element 104 is connected to the node N6. The switching elements 103 and 104 include, for example, at least one of an n-channel MOSFET and a p-channel MOSFET. The switching elements 103 and 104 are normally-off switching elements.

Note that, in the semiconductor device 1C, it may be configured such that the driver circuits 61 and 62 and the control terminals T6 and T7 are not mounted, and the driver circuits 11 and 12 and the control terminals T1 and T2 are shared, as in the second embodiment. Further, in the semiconductor device 1C, it may be configured such that the QN-off driver circuits 101 and 102 and the control terminals T12 and T13 are not mounted, and the ON-off driver circuits 91 and 92 and the control terminals T10 and T11 are shared. In this case, the control electrode of the switching element 103 is connected to the QN-off driver circuit 91. The control electrode of the switching element 104 is connected to the QN-off driver circuit 92.

A case where the switching elements 13, 14, 63, and 64 are n-channel MOSFETs and the switching elements 93, 94, 103, and 104 are p-channel MOSFETs will be described below as an example.

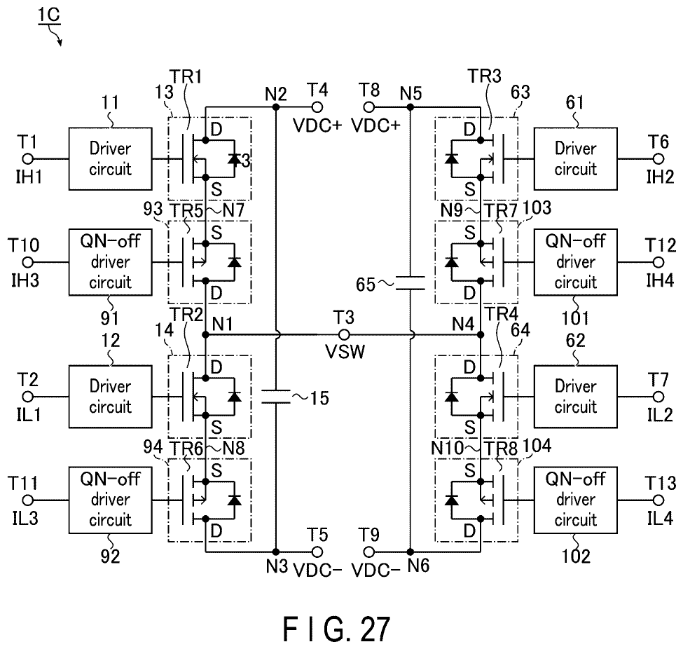

FIG. 27 is a circuit diagram showing an example of a configuration of each switching element in the semiconductor device 1C.

As shown in FIG. 27, the switching element 63 is the transistor TR3. The switching element 64 is the transistor TR4. The transistors TR3 and TR4 are n-channel MOSFETs. The transistors TR3 and TR4 are normally-on transistors.

The source electrode of the switching element 63 is connected to the node N9. The source electrode of the switching element 64 is connected to the node N10.

The switching element 103 is a transistor TR7. The switching element 104 is a transistor TR8. The transistors TR7 and TR8 are p-channel MOSFETs. The transistors TR7 and TR8 are normally-off transistors.

The switching elements 13, 14, 93, and 94 are similar to those in FIG. 22 described in the third embodiment.

The gate electrode (control electrode) of the switching element 103 is connected to the QN-off driver circuit 101. The drain electrode of the switching element 103 is connected to the node N4. The source electrode of the switching element 103 is connected to the node N9. The gate electrode (control electrode) of the switching element 104 is connected to the QN-off driver circuit 102. The drain electrode of the switching element 104 is connected to the node N6. The source electrode of the switching element 104 is connected to the node N10.

The source electrode of the switching element 63 and the source electrode of the switching element 103 are connected in series. The drain electrode of the switching element 103 and the drain electrode of the switching element 64 are connected in series. The source electrode of the switching element 64 and the source electrode of the switching element 104 are connected in series.

### 4.2 Structure of Semiconductor Device

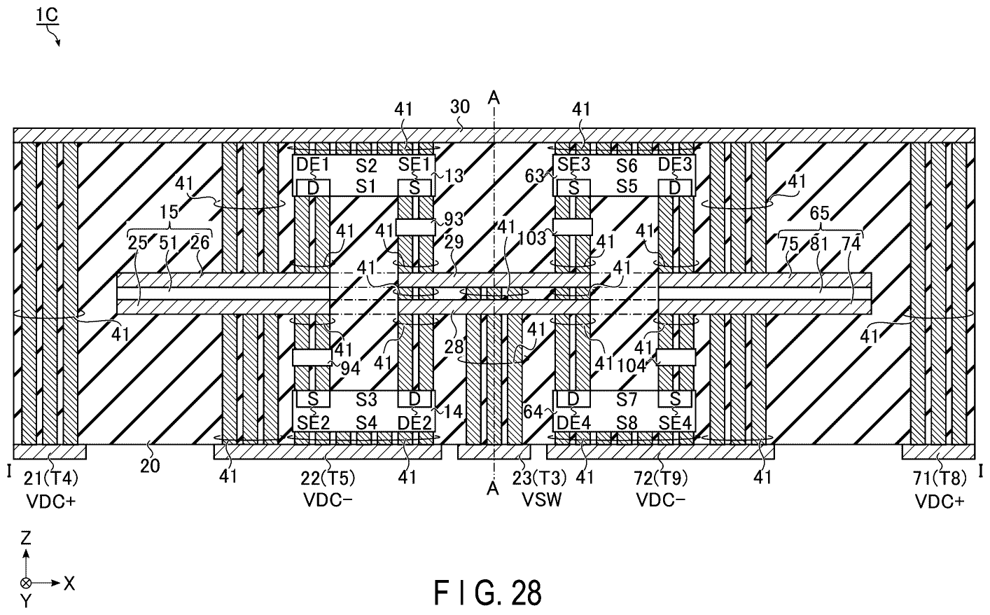

The structure of the semiconductor device 1C will be described. The semiconductor device 1C has a structure combining two semiconductor devices 1B. FIG. 28 is a sectional view showing an example of a sectional structure of the semiconductor device 1C taken along the same line as the line I-I in FIG. 4 described in the first embodiment.

As shown in FIG. 28, in the semiconductor device 1C, with a line A-A as the boundary, the left structure along the X-axis has the same structure as the semiconductor device 1B, and the right structure along the X-axis has a structure obtained by rotating the semiconductor device 1B by 180° around the line A-A as the rotation axis. The switching element 103 corresponds to the switching element 93. The switching element 104 corresponds to the switching element 94.

The switching element 103 is provided above the wiring layer 29. The drain electrode (not shown) of the switching element 103 is connected to the wiring layer 29 via multiple vias 41. The switching element 63 is provided above the switching element 103. The source electrode (not shown) of the switching element 103 is connected to the source electrode SE3 of the switching element 63 via the multiple vias 41. The drain electrode of the switching element 103 is provided, for example, on the surface (the surface facing the wiring layer 29 in the Z direction) of the switching element 103. The source electrode of the switching element 103 is provided, for example, on the surface (the surface facing the source electrode SE3 of the switching element 63 in the Z direction) of the switching element 103.

The switching element 104 is provided below the wiring layer 74. The drain electrode (not shown) of the switching element 104 is connected to the wiring layer 74 via the multiple vias 41. The switching element 64 is provided below the switching element 104. The source electrode (not shown) of the switching element 104 is connected to the source electrode SE4 of the switching element 64 via the multiple vias 41. The drain electrode of the switching element 104 is provided, for example, on the surface (the surface facing the wiring layer 74 in the Z direction) of the switching element 104. The source electrode of the switching element 104 is provided, for example, on the surface (the surface facing the source electrode SE4 of the switching element 64 in the Z direction) of the switching element 104.

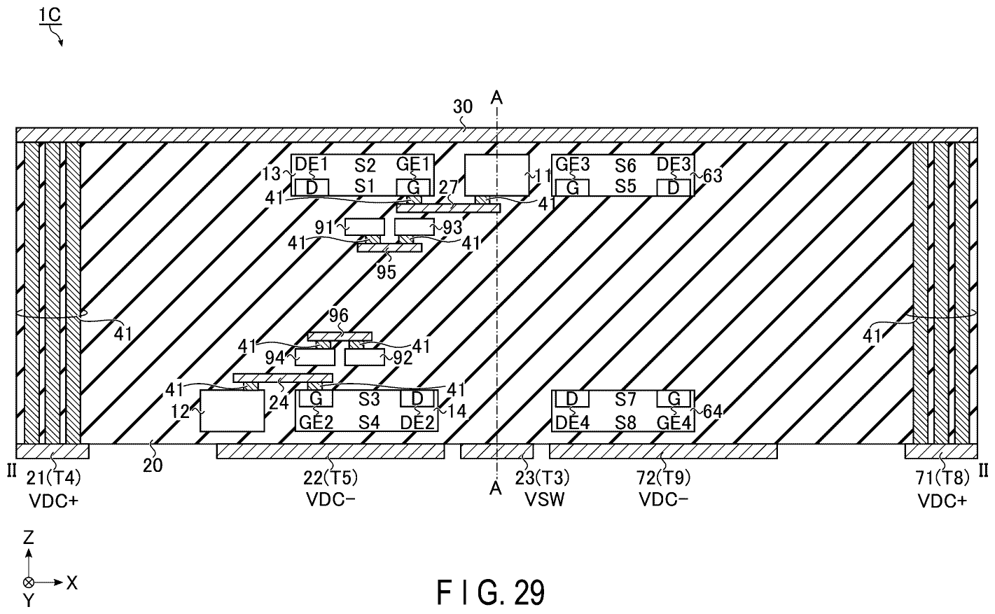

FIG. 29 is a sectional view showing an example of a sectional structure of the semiconductor device 1C taken along the same line as the line II-II in FIG. 4.

As shown in FIG. 29, in the semiconductor device 1C, the sectional structure along the same line as the line II-II in FIG. 4 is different between the left structure along the X-axis and the right structure along the X-axis with the line A-A as the boundary.

The gate electrode GE3 is provided in the vicinity of the front surface of the switching element 63. The gate electrode GE4 is provided in the vicinity of the front surface of the switching element 64.

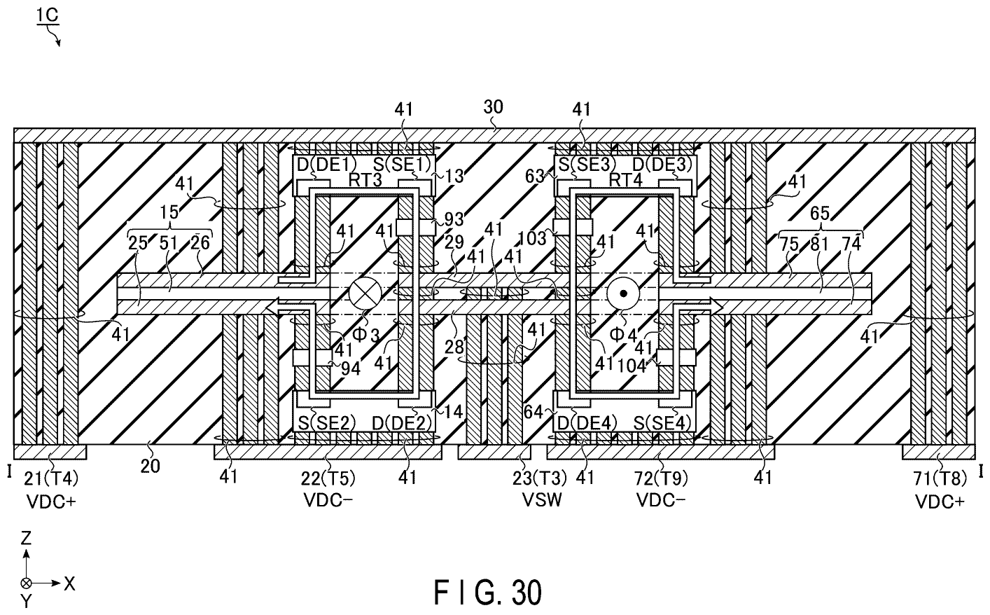

FIG. 30 is a view showing high frequency current paths of the semiconductor device 1C and a magnetic flux generated by a high frequency current.

As shown in FIG. 30, the high frequency current paths of the semiconductor device 1C includes the path (to be referred to as a “third path RT3” hereinafter) in FIG. 25 described in the third embodiment.

The semiconductor device 1C also includes a path (to be referred to as a “fourth path RT4” hereinafter) from the wiring layer 75 to the wiring layer 74 through the via 41 on the wiring layer 75, the drain electrode DE3, the source electrode SE3, the via 41 under the source electrode SE3, the switching element 103, the via 41 under the switching element 103, the wiring layer 29, the via 41 under the wiring layer 29, the wiring layer 28, the via 41 under the wiring layer 28, the drain electrode DE4, the source electrode SE4, the via 41 on the source electrode SE4, the switching element 104, and the via 41 on the switching element 104.

Due to the above-described configuration, in this embodiment, the length of the high frequency current path is short in each of the third path RT3 and the fourth path RT4, similarly to the first embodiment. Hence, the parasitic inductance of the loop consisting of the capacitor 15 and the switching elements 13, 14, 93, and 94 can be reduced. The parasitic inductance of the loop consisting of the capacitor 65 and the switching elements 63, 64, 103, and 104 can be reduced. Accordingly, this embodiment has an effect similar to that of the first embodiment.

Further, as shown in FIG. 30, in this embodiment, the direction (the direction from the front side to the back side of the drawing surface) of a magnetic flux Φ3 generated by the high frequency current flowing through the third path RT3 is opposite to the direction (the direction from the back side to the front side of the drawing surface) of a magnetic flux Φ4 generated by the high frequency current flowing through the fourth path RT4. Therefore, the magnetic fluxes respectively generated in the two paths RT3 and RT4 cancel each other. Thus, noise discharged to the outside due to the generation of the magnetic flux can be suppressed. Accordingly, this embodiment has an effect similar to that of the second embodiment.

### 5. Modifications and the Like

As has been described, a semiconductor device (1) according to the embodiment includes a first switch (13) provided with a first electrode (DE1) and a second electrode (SE1) in a vicinity of a front surface (S1), a second switch (14) provided with a third electrode (SE2) and a fourth electrode (DE2) in a vicinity of a front surface (S3), a first capacitor (15) including a first wiring layer (25) connected to the third electrode (SE2), a second wiring layer (26) connected to the first electrode (DE1), and a first dielectric layer (51) arranged between the first wiring layer and the second wiring layer, a substrate (20) incorporating the first switch (13), the second switch (14), and the first capacitor (15), a third wiring layer (22 (T5)) connected to the first wiring layer (25) and applied with a first voltage (VDC−), a fourth wiring layer (21 (T4)) connected to the second wiring layer (26) and applied with a second voltage (VDC+) higher than the first voltage (VDC−), and a fifth wiring layer (23 (T3)) connected to the second electrode (SE1) and the fourth electrode (DE2), and applied with a third voltage (VSW) in a range of not less than the first voltage (VDC−) and not more than the second voltage (VDC+). The first capacitor (15) is arranged between the first switch (13) and the second switch (14). The third electrode (SE2) is arranged to face the first electrode (DE1) in a first direction (Z). The fourth electrode (DE2) is arranged to face the second electrode (SE1) in the first direction (Z) and connected to the second electrode (SE1) in series.

Note that the embodiments are not limited to the above-described embodiments, and various modifications can be made.

In this specification, the term “connect” refers to being electrically connected, and does not exclude, for example, the presence of another element therebetween.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a first switch provided with a first electrode and a second electrode in a vicinity of a front surface;
a second switch provided with a third electrode and a fourth electrode in a vicinity of a front surface;
a first capacitor including a first wiring layer connected to the third electrode, a second wiring layer connected to the first electrode, and a first dielectric layer arranged between the first wiring layer and the second wiring layer;
a substrate incorporating the first switch, the second switch, and the first capacitor;
a third wiring layer connected to the first wiring layer and applied with a first voltage;
a fourth wiring layer connected to the second wiring layer and applied with a second voltage higher than the first voltage; and
a fifth wiring layer connected to the second electrode and the fourth electrode and applied with a third voltage in a range of not less than the first voltage and not more than the second voltage,
wherein the first capacitor is arranged between the first switch and the second switch,
the third electrode is arranged to face the first electrode in a first direction, and
the fourth electrode is arranged to face the second electrode in the first direction and connected to the second electrode in series.

2. The device according to claim 1, wherein
the first electrode and the second electrode are arranged to face each other in a second direction intersecting the first direction, and
the third electrode and the fourth electrode are arranged to face each other in the second direction.

3. The device according to claim 1, wherein
a thickness of the first dielectric layer is smaller than a thickness of the first switch and smaller than a thickness of the second switch.

4. The device according to claim 1, wherein
the first dielectric layer includes silicon or barium titanate.

5. The device according to claim 1, wherein
an area of a front surface of the second wiring layer is larger than an area of the front surface of the first switch, and
an area of a front surface of the first wiring layer is larger than an area of the front surface of the second switch.

6. The device according to claim 1, wherein
the second wiring layer protrudes from the second switch along a second direction intersecting the first direction, and
the first wiring layer protrudes from the first switch along the second direction.

7. The device according to claim 1, further comprising
a sixth wiring layer connected to the second wiring layer and the fourth wiring layer,
wherein a back surface of the first switch is connected to the sixth wiring layer via at least one first via, and
a back surface of the second switch is connected to the third wiring layer via at least one second via.

8. The device according to claim 1, further comprising:
a third switch provided with a fifth electrode and a sixth electrode in a vicinity of a front surface;
a fourth switch provided with a seventh electrode and an eighth electrode in a vicinity of a front surface;
a second capacitor including a seventh wiring layer connected to the seventh electrode, an eighth wiring layer connected to the fifth electrode, and a second dielectric layer arranged between the seventh wiring layer and the eighth wiring layer;
a ninth wiring layer connected to the seventh wiring layer and applied with the first voltage; and
a tenth wiring layer connected to the eighth wiring layer and applied with the second voltage,
wherein the third switch, the fourth switch, and the second capacitor are incorporated in the substrate,
the fifth wiring layer is connected to the sixth electrode and the eighth electrode,
the second capacitor is arranged between the third switch and the fourth switch,
the seventh electrode is arranged to face the fifth electrode in the first direction, and
the eighth electrode is arranged to face the sixth electrode in the first direction and connected to the sixth electrode in series.

9. The device according to claim 8, wherein
the fifth electrode and the sixth electrode are arranged to face each other in a second direction intersecting the first direction, and
the seventh electrode and the eighth electrode are arranged to face each other in the second direction.

10. The device according to claim 1, wherein
an area of a front surface of the fifth wiring layer is smaller than an area of a front surface of the third wiring layer.

11. The device according to claim 1, wherein
the first switch and the second switch include at least one of an n-channel MOSFET, a p-channel MOSFET, a GaN transistor, an SiC (Silicon Carbide) transistor, an IGBT (Insulated Gate Bipolar Transistor), and a JFET.

12. A semiconductor device comprising:
a first switch provided with a first electrode and a second electrode in a vicinity of a front surface;
a second switch provided with a third electrode and a fourth electrode in a vicinity of a front surface;
a substrate incorporating the first switch and the second switch;
a first wiring layer connected to the third electrode and applied with a first voltage;
a second wiring layer connected to the first electrode and applied with a second voltage higher than the first voltage; and
a third wiring layer connected to the second electrode and the fourth electrode and applied with a third voltage in a range of not less than the first voltage and not more than the second voltage,
wherein the third electrode is arranged to face the first electrode in a first direction, and
the fourth electrode is arranged to face the second electrode in the first direction and connected to the second electrode in series.

13. The device according to claim 12, wherein
the first electrode and the second electrode are arranged to face each other in a second direction intersecting the first direction, and
the third electrode and the fourth electrode are arranged to face each other in the second direction.

14. The device according to claim 12, further comprising:
a third switch provided with a fifth electrode and a sixth electrode in a vicinity of a front surface;
a fourth switch provided with a seventh electrode and an eighth electrode in a vicinity of a front surface;
a fourth wiring layer connected to the seventh electrode and applied with the first voltage; and
a fifth wiring layer connected to the fifth electrode and applied with the second voltage,
wherein the third switch and the fourth switch are incorporated in the substrate,
the third wiring layer is connected to the sixth electrode and the eighth electrode,
the seventh electrode is arranged to face the fifth electrode in the first direction, and
the eighth electrode is arranged to face the sixth electrode in the first direction and connected to the sixth electrode in series.

15. The device according to claim 14, wherein
the fifth electrode and the sixth electrode are arranged to face each other in a second direction intersecting the first direction, and
the seventh electrode and the eighth electrode are arranged to face each other in the second direction.

16. A semiconductor device comprising:
a first switch provided with a first electrode and a second electrode in a vicinity of a front surface;
a second switch provided with a third electrode and a fourth electrode in a vicinity of a front surface;
a third switch;
a fourth switch;
a first capacitor including a first wiring layer connected to the fourth switch and connected to the third electrode via the fourth switch, a second wiring layer connected to the first electrode, and a first dielectric layer arranged between the first wiring layer and the second wiring layer;
a substrate incorporating the first switch, the second switch, the third switch, the fourth switch, and the first capacitor;
a third wiring layer connected to the first wiring layer and applied with a first voltage;
a fourth wiring layer connected to the second wiring layer, and applied with a second voltage higher than the first voltage; and
a fifth wiring layer connected to the third switch and the fourth electrode, connected to the second electrode via the third switch, and applied with a third voltage in a range of not less than the first voltage and not more than the second voltage,
wherein the first capacitor is arranged between the first switch and the second switch,
the third electrode is arranged to face the first electrode in a first direction,
the fourth electrode is arranged to face the second electrode in the first direction and connected to the third switch in series,
the third switch is provided between the second electrode and the fourth electrode, and
the fourth switch is provided between the first electrode and the third electrode.

17. The device according to claim 16, wherein
the first electrode and the second electrode are arranged to face each other in a second direction intersecting the first direction, and
the third electrode and the fourth electrode are arranged to face each other in the second direction.

18. The device according to claim 16, further comprising:
a fifth switch provided with a fifth electrode and a sixth electrode in a vicinity of a front surface;
a sixth switch provided with a seventh electrode and an eighth electrode in a vicinity of a front surface;
a seventh switch;
an eighth switch;
a second capacitor including a sixth wiring layer connected to the eighth switch and connected to the seventh electrode via the eighth switch, a seventh wiring layer connected to the fifth electrode, and a second dielectric layer arranged between the sixth wiring layer and the seventh wiring layer;
an eighth wiring layer connected to the sixth wiring layer and applied with the first voltage; and
a ninth wiring layer connected to the seventh wiring layer and applied with the second voltage,
wherein the fifth switch, the sixth switch, the seventh switch, the eighth switch, and the second capacitor are incorporated in the substrate,
the fifth wiring layer is connected to the seventh switch and the seventh electrode, and connected to the sixth electrode via the seventh switch,
the second capacitor is arranged between the fifth switch and the sixth switch,
the seventh electrode is arranged to face the fifth electrode in the first direction,
the eighth electrode is arranged to face the sixth electrode in the first direction and connected to the seventh switch in series,
the seventh switch is provided between the sixth electrode and the eighth electrode, and
the eighth switch is provided between the fifth electrode and the seventh electrode.

19. The device according to claim 18, wherein
the fifth electrode and the sixth electrode are arranged to face each other in a second direction intersecting the first direction, and
the seventh electrode and the eighth electrode are arranged to face each other in the second direction.
